(19) United States
(12) Patent Application Publication
(10) Pub. No.: US 2011/0274234 A1
(43) Pub. Date: Nov. 10, 2011

(54) SHIFT REGISTER

(75) Inventors: Mayuko Sakamoto, Osaka (JP); Masao Moriguchi, Osaka (JP); Yasuaki Iwase, Osaka (JP); Yuhichi Saitoh, Osaka (JP); Tokuo Yoshida, Osaka (JP); Yohsuke Kanzaki, Osaka (JP)

(73) Assignee: SHARP KABUSHIKI KAISHA

(21) Appl. No.: 12/998,686

(22) PCT Filed: Nov. 19, 2009
(86) PCT No.: PCT/JP2009/006227

§ 371 Date: Jun. 7, 2011

(30) Foreign Application Priority Data
Nov. 20, 2008 (JP) 2008-297297

(51) Int. Cl. G11C 19/00

(52) U.S. Cl. 377/64

(57) ABSTRACT

A shift register of at least one embodiment of the present invention is a shift register supported by an insulative substrate, wherein: the shift register includes a plurality of stages each sequentially outputting output signals; each of the plurality of stages includes a first transistor for outputting the output signals, and a plurality of second transistors whose source region or drain region is electrically connected to a gate electrode of the first transistor; and the plurality of second transistors include a multi-channel transistor having an active layer including at least two channel regions, a source region and a drain region. This improves characteristics of a shift register forming a monolithic gate driver.

### TECHNICAL FIELD

The present invention relates to a shift register, and more particularly to a shift register provided in an active matrix substrate of a liquid crystal display panel or an organic EL display panel.

### BACKGROUND ART

In recent years, liquid crystal display devices and organic EL display devices are becoming widespread which include a thin film transistor (hereinafter “TFT”) for each pixel. TFTs are made by using the semiconductor layer formed on a substrate such as a glass substrate. A substrate on which TFTs are formed is referred to as an active matrix substrate.

Conventionally, TFTs using an amorphous silicon film as the active layer (hereinafter “amorphous silicon TFTs”) and TFTs using a polycrystalline silicon film as the active layer (hereinafter “polycrystalline silicon TFTs”) are widely used as TFTs.

Since the carrier mobility of a polycrystalline silicon film is higher than an amorphous silicon film, a polycrystalline silicon TFT has a higher ON current than an amorphous silicon TFT and is capable of high-speed operation. In view of this, display panels have been developed in which not only TFTs for pixels but also some or all of TFTs for peripheral circuits such as drivers are formed by polycrystalline silicon TFTs. Drivers thus formed on an insulative substrate (typically, a glass substrate) forming a display panel may be called monolithic drivers. Drivers include a gate driver and a source driver, and only one of these may be a monolithic driver. Herein, a display panel refers to a portion of a liquid crystal display device or an organic EL display device including a display region, and does not include a backlight, a bezel, or the like, of the liquid crystal display device.

The production of polycrystalline silicon TFTs requires complicated processes such as a thermal annealing process or an ion doping process as well as a laser crystallization process for crystallizing an amorphous silicon film. Thus, currently, polycrystalline silicon TFTs are used mainly in medium and small display devices, and amorphous silicon TFTs are used in large display devices. In recent years, with increasing demands for increasing the image quality and reducing the power consumption in addition to increasing the size of display devices, proposals have been made (Patent Document No. 1, Patent Document No. 2 and Non-Patent Document No. 1) of TFTs using a micro-crystalline silicon (μc-Si) film as the active layer which have higher performance and lower manufacturing cost than amorphous TFTs. Such a TFT is called a “micro-crystalline silicon TFT”.

A micro-crystalline silicon film is a silicon film having the crystalline phase and the amorphous phase, and has a composition in which micro-crystal particles are dispersed in the amorphous phase. Each micro-crystal particle has a size (several hundreds nm or less) smaller than the size of a crystal particle included in the polycrystalline silicon film, and may be a columnar crystal.

The micro-crystalline silicon film can be formed by using a plasma CVD method, or the like, and does not require a heat treatment for crystallization, and therefore the facilities for manufacturing an amorphous silicon film can be used as they are. Since a micro-crystalline silicon film has higher carrier mobility than an amorphous silicon film, it is possible to obtain a TFT having higher performance than an amorphous silicon TFT.

For example, Patent Document No. 1 states that by using a micro-crystalline silicon film as the active layer of TFTs, it is possible to obtain an ON current that is 1.5 times that with an amorphous silicon TFT. Non-Patent Document No. 1 states that by using a semiconductor film made of micro-crystalline silicon and amorphous silicon, it is possible to obtain a TFT having an ON/OFF current ratio of 10⁶, a mobility of about 1 cm²/Vs and a threshold value of about 5 V.

Moreover, Patent Document No. 2 discloses an inverted staggered TFT using micro-crystalline silicon.

Although micro-crystalline silicon TFTs have such advantages as described above, they have not yet been put to practical use. One reason is that a micro-crystalline silicon TFT has a high OFF current (=leak current).

It is possible to employ a multi-channel structure (referred to also as a multi-gate structure) used in polycrystalline silicon TFTs as a method for reducing the OFF current of TFTs. For example, Patent Document Nos. 3 and 4 disclose a liquid crystal display device and an organic EL display device using micro-crystalline silicon TFTs having a multi-gate channel structure. In these display devices, a multi-channel structure is employed for pixel TFTs, thereby reducing the OFF current of pixel TFTs and improving the voltage retention property of pixels.

### CITATION LIST

### Patent Literature

Patent Document No. 1: Japanese Laid-Open Patent Publication No. 6-196701

Patent Document No. 2: Japanese Laid-Open Patent Publication No. 5-304171

Patent Document No. 3: Japanese Laid-Open Patent Publication No. 2005-51211

Patent Document No. 4: Japanese Laid-Open Patent Publication No. 2005-49832

### Non-Patent Literature

Non-Patent Document No. 1: Zhongyang Xu, et al., “A Novel Thin-film Transistors With μc-Si/a-Si Dual Active Layer Structure For AM-LCD” IDW'96 Proceedings of The Third International Display Workshops VOLUME 1, 1996, p. 117-120

### SUMMARY OF INVENTION

### Technical Problem

However, it has been found by a study of the present inventor that even if the OFF current of pixel TFTs is reduced, the display quality lowers or in some cases display cannot be produced when micro-crystalline silicon TFTs are used in the shift register forming the gate driver.

It has been found that this problem occurs because there is a large leak current in the sub-threshold region (the gate voltage Vg≧0 V) of some TFTs forming the shift register, thereby lowering the voltage of the gate electrode of the output transistor (pull-up transistor) of the shift register so that the output waveform is blunted or the output transistor is not turned ON, as will be described later.

The voltage Vds applied between the source and the drain of some TFTs forming the shift register is higher than the voltage Vds applied between the source and the drain of pixel TFTs, and may reach around 50 V at maximum for a medium liquid crystal display panel and may reach around 70 V at maximum for a large liquid crystal display panel, for example. While the problem is the OFF current when the gate voltage Vg (Vgs) is in a negative region for pixel TFTs, the gate voltage Vg (Vgs) of a TFT forming the shift register is around 0 V. For example, the relationship between the gate voltage Vg and the source-drain current Ids (referred to also as the Ids-Vg characteristics) of a micro-crystalline silicon TFT having a single-channel structure shown in FIG. 20 shows that Ids at Vg=0 V for Vds=40 V is greater than Ids for Vds=10 V by three orders of magnitude.

Note that the problem of TFT leak current in the sub-threshold region due to a high voltage applied as Vds described above also occurs in an amorphous silicon TFT. As the size of a liquid crystal display panel increases, techniques for forming drivers using amorphous silicon TFTs have been developed. Note that as a semiconductor material used in a TFT as an amorphous semiconductor film or a micro-crystalline semiconductor film, silicon germanium (SiGe) and silicon carbide (SiC) are known as well as silicon (Si), and have similar problems to those described above.

As described above, the use of an amorphous semiconductor film or a micro-crystalline semiconductor film provides an advantage that the manufacturing cost is lower than that when a polycrystalline semiconductor film is used, but the problem of the leak current in some TFTs forming the shift register is a problem that occurs irrespective of the type of the semiconductor film.

The present invention has been made in view of the problems described above, and a primary object thereof is to improve the characteristics of a shift register forming a monolithic gate driver.

Another object of the present invention is to provide a multi-channel TFT capable of reducing the OFF current as compared with a conventional multi-channel TFT described in Patent Document No. 3 or 4.

### Solution to Problem

A shift register of the present invention is a shift register supported by an insulative substrate, wherein: the shift register includes a plurality of stages each sequentially outputting output signals; each of the plurality of stages includes a first transistor for outputting the output signals, and a plurality of second transistors whose source region or drain region is electrically connected to a gate electrode of the first transistor; and the plurality of second transistors include a multi-channel transistor having an active layer including at least two channel regions, a source region and a drain region.

In an embodiment, one of the plurality of second transistors having a highest source-drain voltage is the multi-channel transistor. Where some of the plurality of second transistors are multi-channel transistors, the source-drain voltage of a multi-channel transistor is higher than the source-drain voltage of one that is not a multi-channel transistor.

In an embodiment, all of the plurality of second transistors are the multi-channel transistors.

In an embodiment, the active layer includes a semiconductor film having an amorphous phase. The semiconductor film having an amorphous phase may be formed only by an amorphous semiconductor film, may be formed by a micro-crystalline semiconductor film, or may be formed by a layered film of an amorphous semiconductor film and a micro-crystalline semiconductor film.

In an embodiment, the semiconductor film is a micro-crystalline semiconductor film. The semiconductor film may be a polycrystalline semiconductor film.

In an embodiment, the active layer includes a polycrystalline semiconductor film.

In an embodiment, the gate electrode of the multi-channel transistor has a portion that overlaps with the source region and the drain region; an area of a portion of the gate electrode that overlaps with the drain region and an area of a portion of the gate electrode that overlaps with the source region are different from each other; and the area of the portion that is connected to the gate electrode of the first transistor is smaller than the area of the portion that is not connected to the gate electrode of the first transistor.

In an embodiment, a source region and a drain region of the first transistor have different sizes from each other, and one that is not connected to a gate bus line is smaller than one that is connected to the gate bus line.

In an embodiment, the active layer of the multi-channel transistor further includes at least one intermediate region formed between the at least two channel regions, and the at least two channel regions include a first channel region formed between the source region and the at least one intermediate region and a second channel region formed between the drain region and the at least one intermediate region; the multi-channel transistor further includes: a contact layer including a source contact region in contact with the source region, a drain contact region in contact with the drain region, and at least one intermediate contact region in contact with the at least one intermediate region; and a source electrode in contact with the source contact region, a drain electrode in contact with the drain contact region, and at least one intermediate electrode in contact with the at least one intermediate contact region; the gate electrode of the multi-channel transistor opposes the at least two channel regions and the at least one intermediate region with a gate insulating film interposed therebetween; and an entirety of a portion of the at least one intermediate electrode that is present between the first channel region and the second channel region overlaps with the gate electrode with the at least one intermediate region and the gate insulating film interposed therebetween.

In an embodiment, the gate electrode of the multi-channel transistor includes a portion that overlaps with the source region and the drain region; and an area of a portion of the gate electrode that overlaps with one of the source region and the drain region that is connected to the gate electrode of the first transistor is smaller than an area of a portion of the gate electrode that overlaps with the at least one intermediate region. When the drain region is connected to the gate electrode of the first transistor, it is preferred that at least the area of the portion of the gate electrode that overlaps with the drain region is smaller than the area of the portion of the gate electrode that overlaps with the at least one intermediate region. Then, the area of the portion of the gate electrode that overlaps with the source region may be smaller than the area of the portion of the gate electrode that overlaps with the at least one intermediate region.

In an embodiment, as seen in a direction vertical to the substrate, the at least one intermediate electrode of the multi-channel transistor includes a depressed portion, and the drain electrode includes a protruding portion in the depressed portion of the at least one intermediate electrode.

In an embodiment, as seen in a direction vertical to the substrate, the source electrode of the multi-channel transistor includes a depressed portion, and the at least one intermediate electrode includes a protruding portion in the depressed portion of the source electrode.

In an embodiment, the at least one intermediate region of the multi-channel transistor includes a first intermediate region and a second intermediate region, the at least one intermediate contact region includes a first intermediate contact region and a second intermediate contact region, and the at least one intermediate electrode includes a first intermediate electrode and a second intermediate electrode; and the at least two channel regions further include a third channel region, with the first channel region formed between the source electrode and the first intermediate electrode, the second channel region formed between the drain electrode and the second intermediate electrode, and the third channel region formed between the first intermediate electrode and the second intermediate electrode.

In an embodiment, the at least one intermediate contact region of the multi-channel transistor serves also as the at least one intermediate electrode.

That is, in an embodiment, the multi-channel transistor includes an active layer supported by a substrate including at least two channel regions, a source region, a drain region and at least one intermediate region formed between the at least two channel regions, a contact layer including a source contact region in contact with the source region, a drain contact region in contact with the drain region and at least one intermediate contact region in contact with the at least one intermediate region, a source electrode in contact with the source contact region, a drain electrode in contact with the drain contact region, and a gate electrode opposing the at least two channel regions and the at least one intermediate region with a gate insulating film interposed therebetween, wherein the at least two channel regions include a first channel region formed between the source region and the at least one intermediate region and a second channel region formed between the drain region and the at least one intermediate region, and an entirety of the portion of the at least one intermediate contact region that is present between the first channel region and the second channel region overlaps with the gate electrode with the at least one intermediate region and the gate insulating film interposed therebetween.

In an embodiment, the active layer is provided between the gate electrode and the substrate.

An active matrix substrate of the present invention includes a shift register according to any of the above paragraphs.

A display panel of the present invention includes a shift register according to any of the above paragraphs.

### Advantageous Effects of Invention

According to the present invention, it is possible to improve characteristics of a shift register using TFTs in which a semiconductor film including an amorphous phase is used as an active layer.

According to the present invention, it is possible to provide a multi-channel TFT capable of reducing the OFF current as compared with conventional techniques. By using the multi-channel TFT, characteristics of a shift register are further improved.

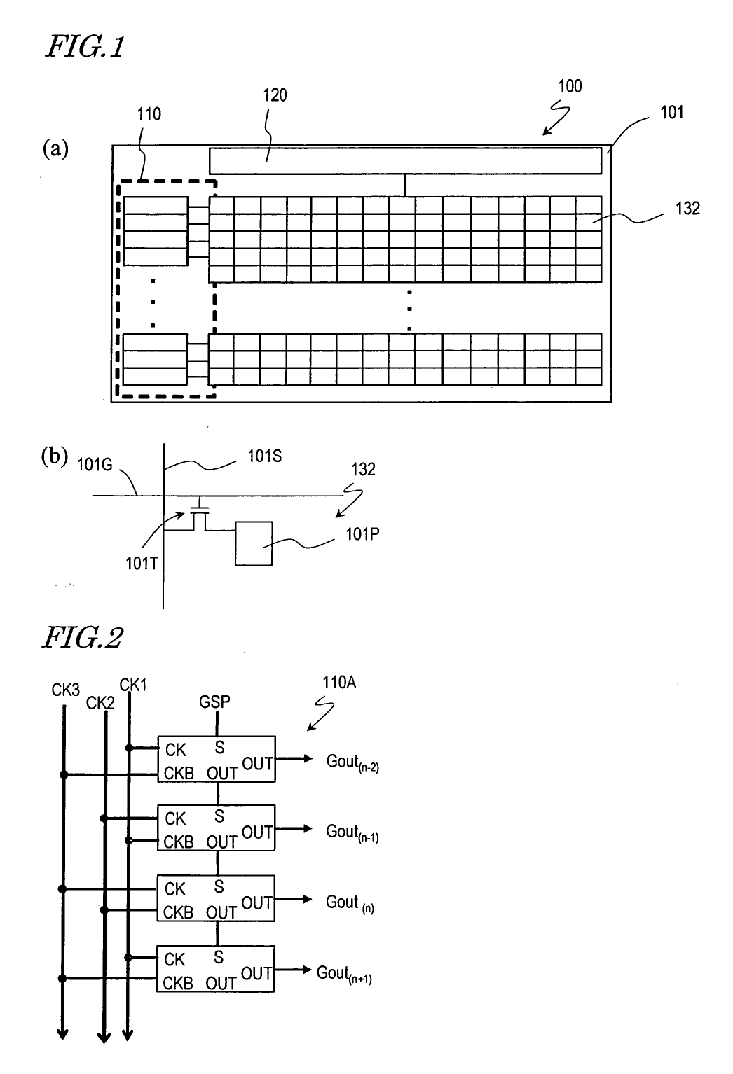

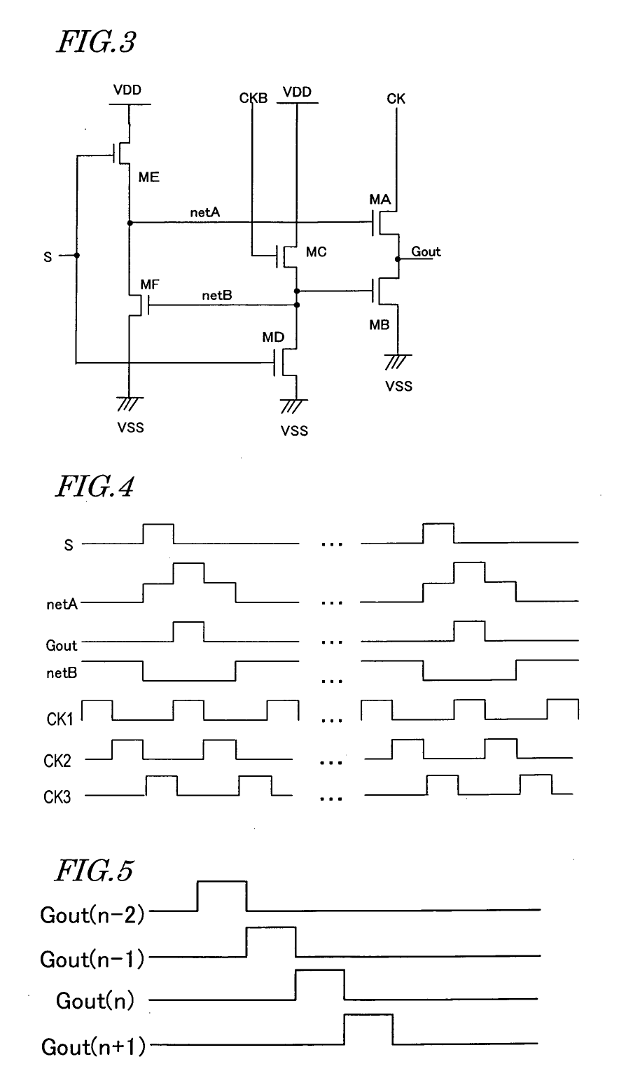

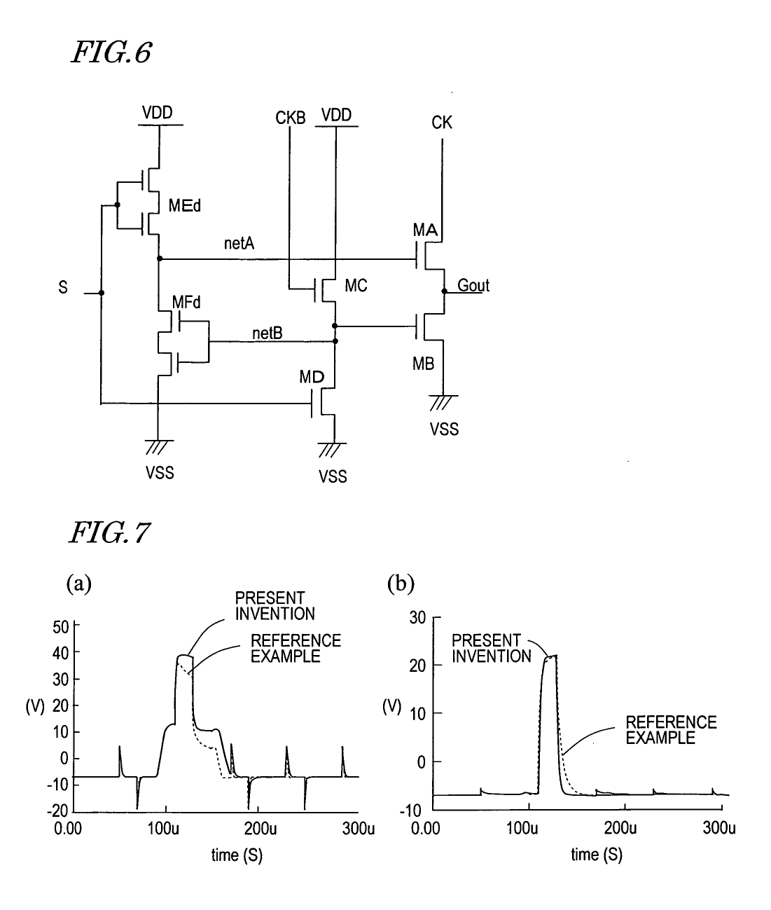

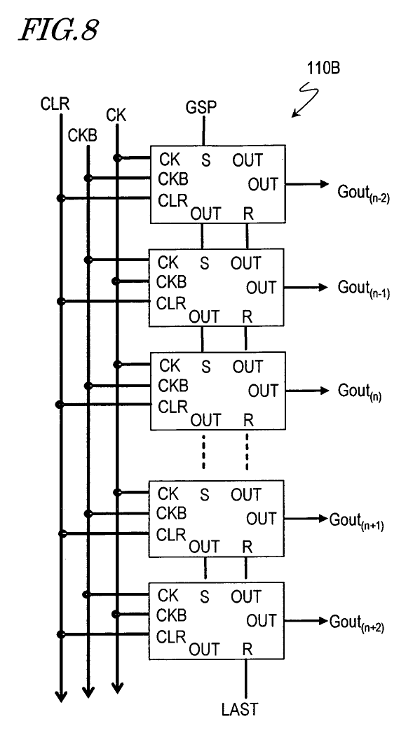

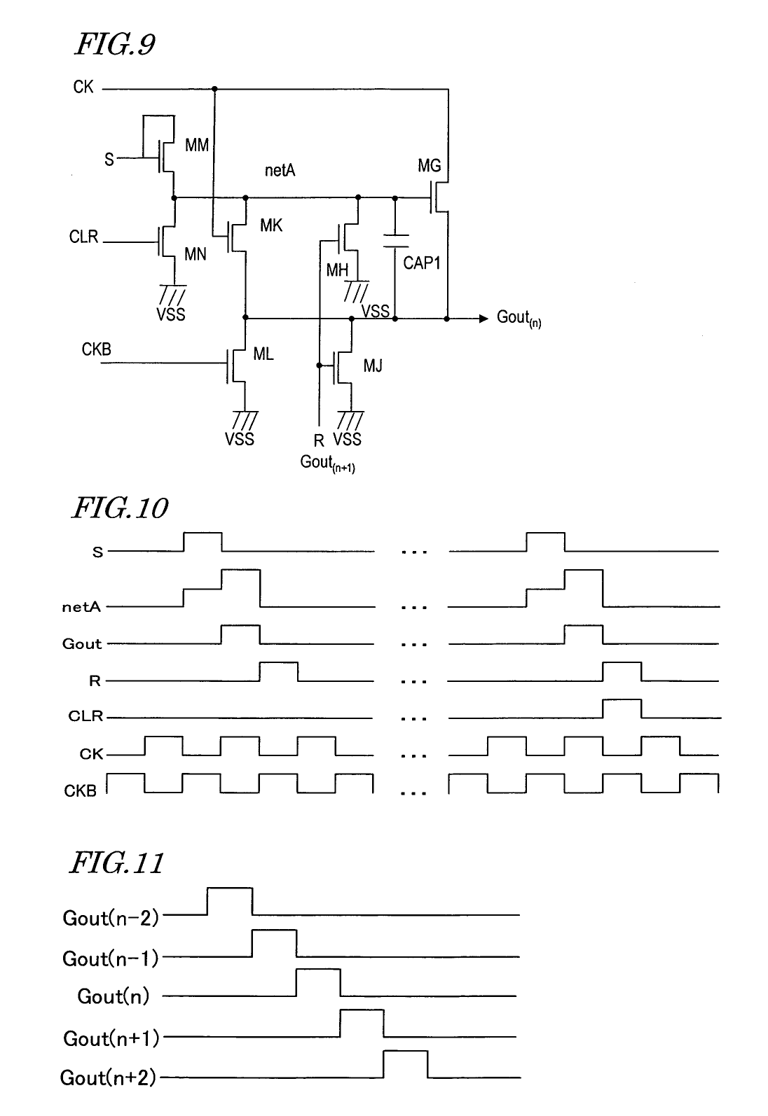

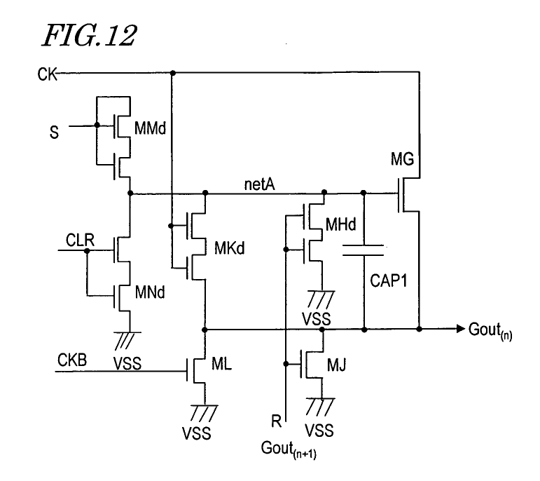

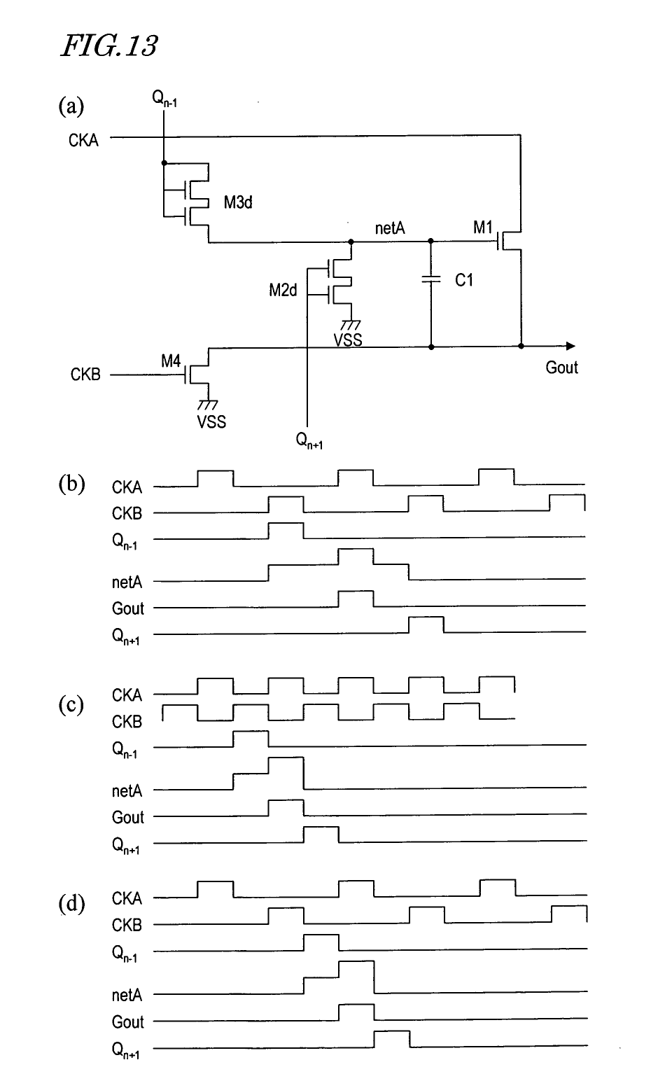

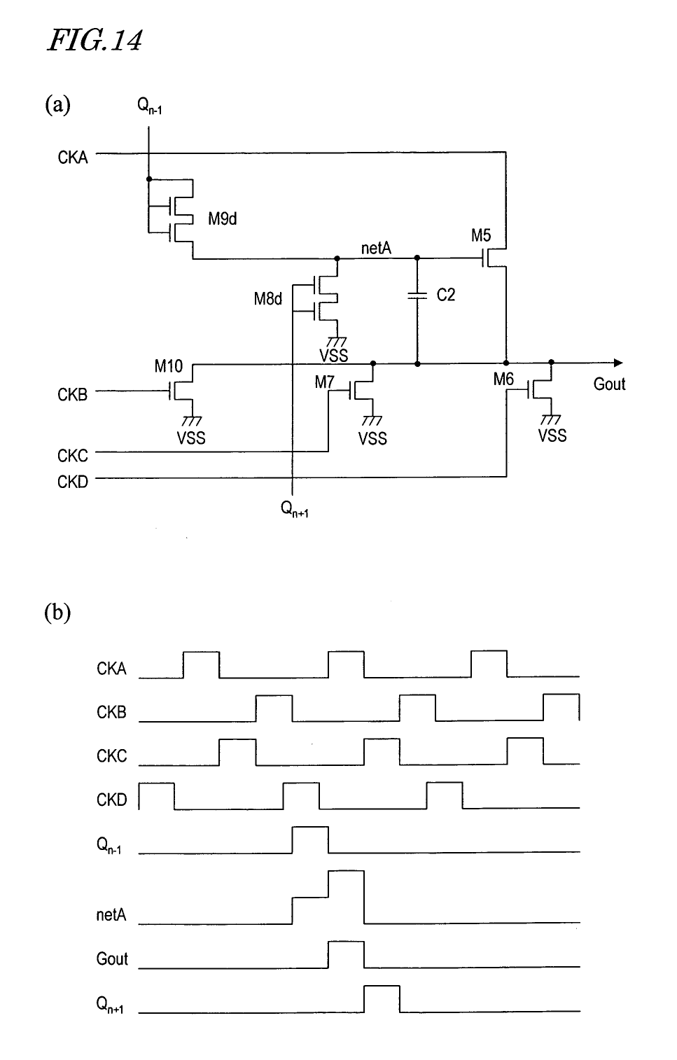

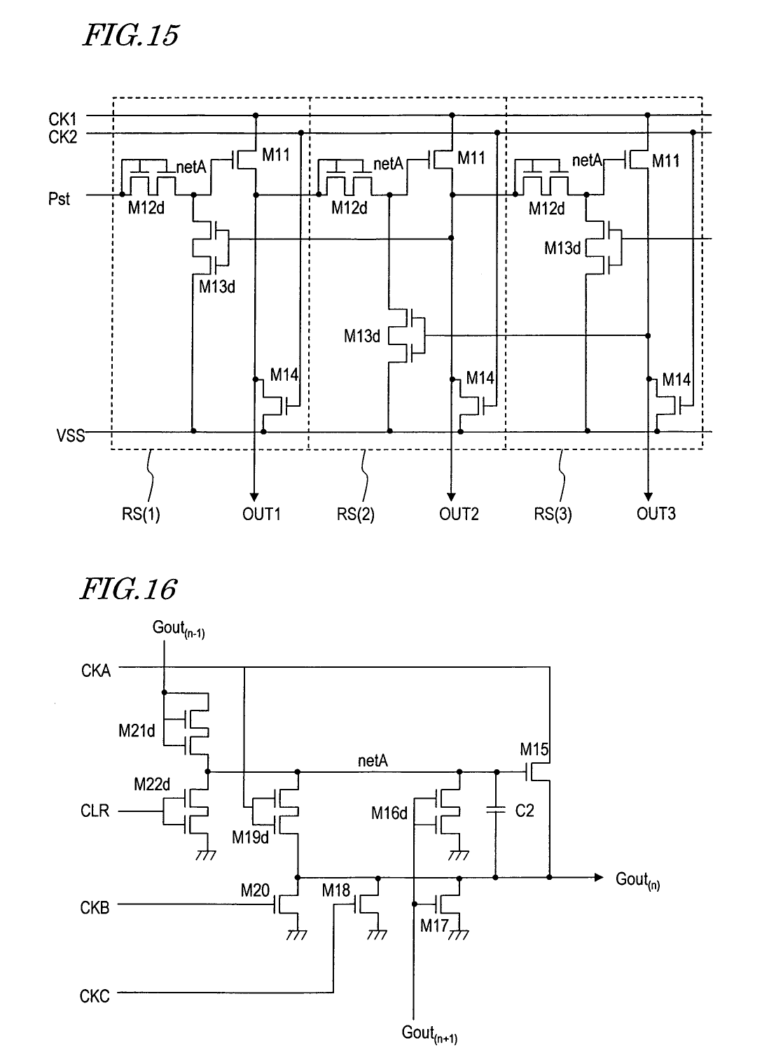

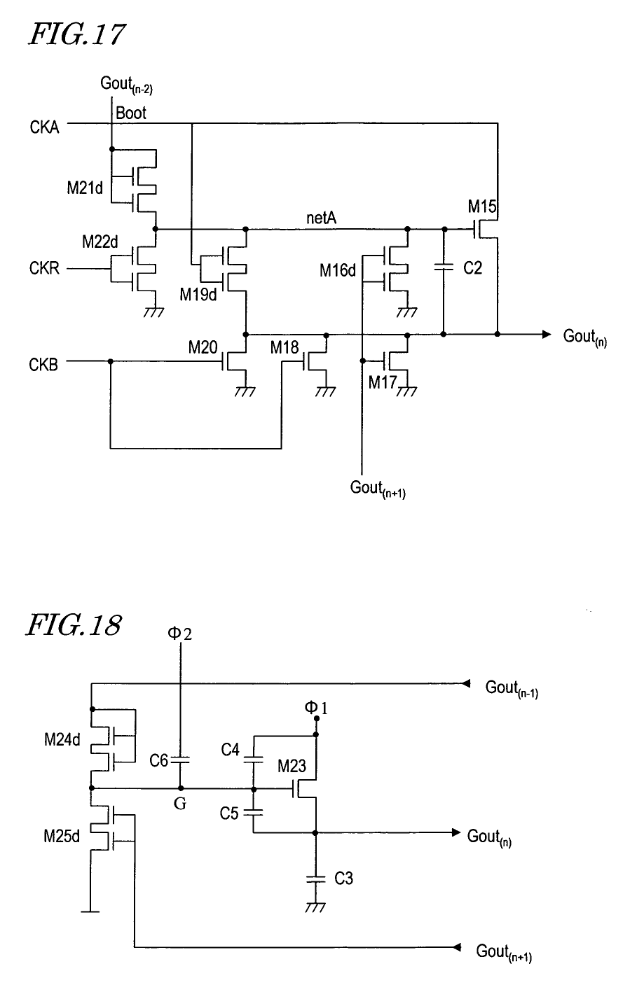

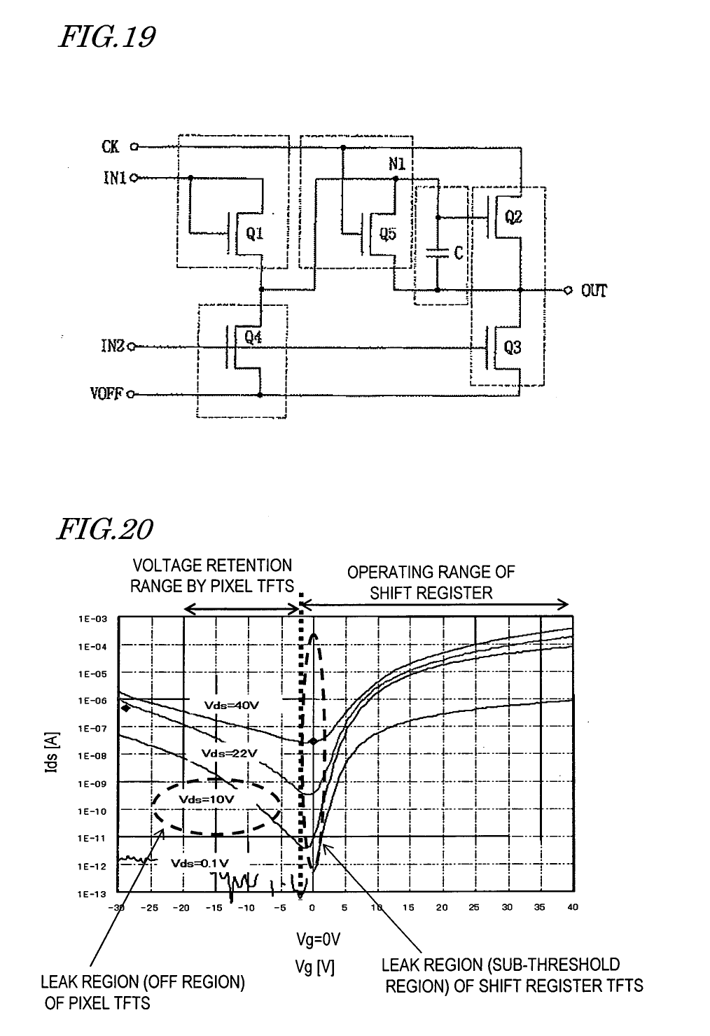

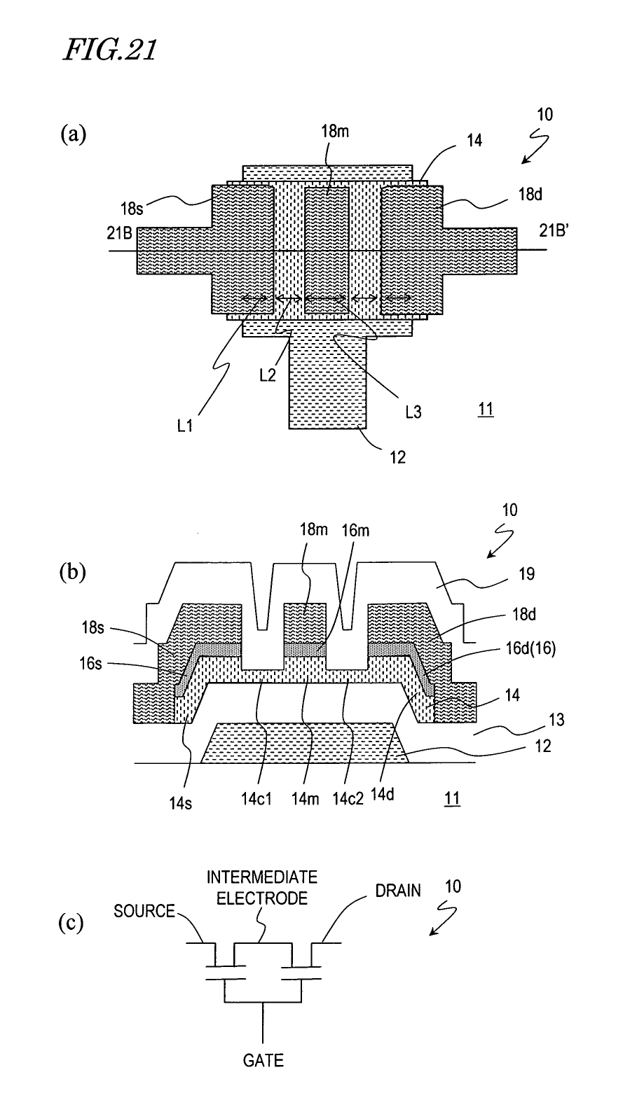

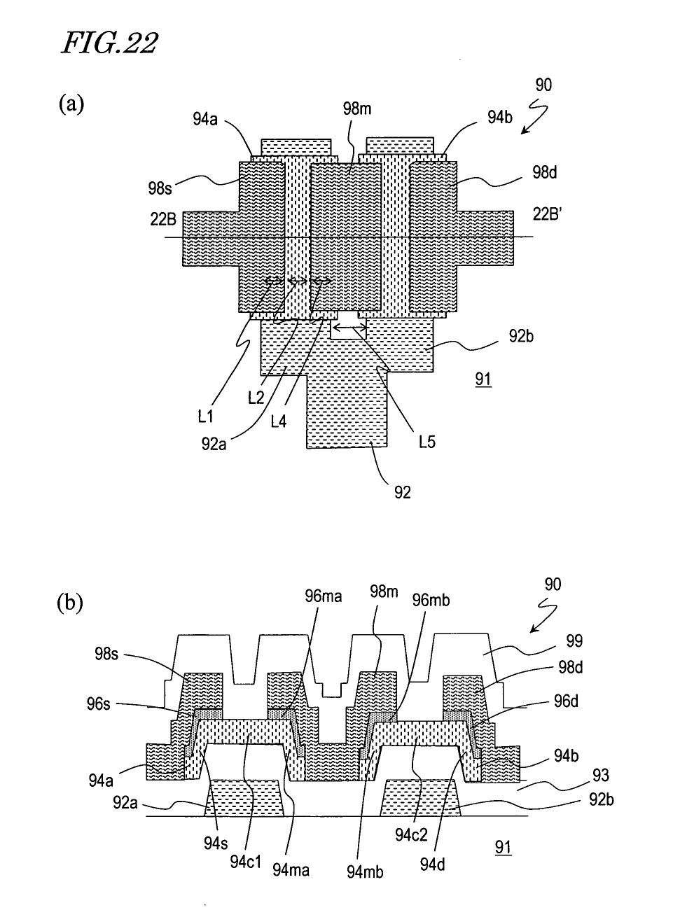

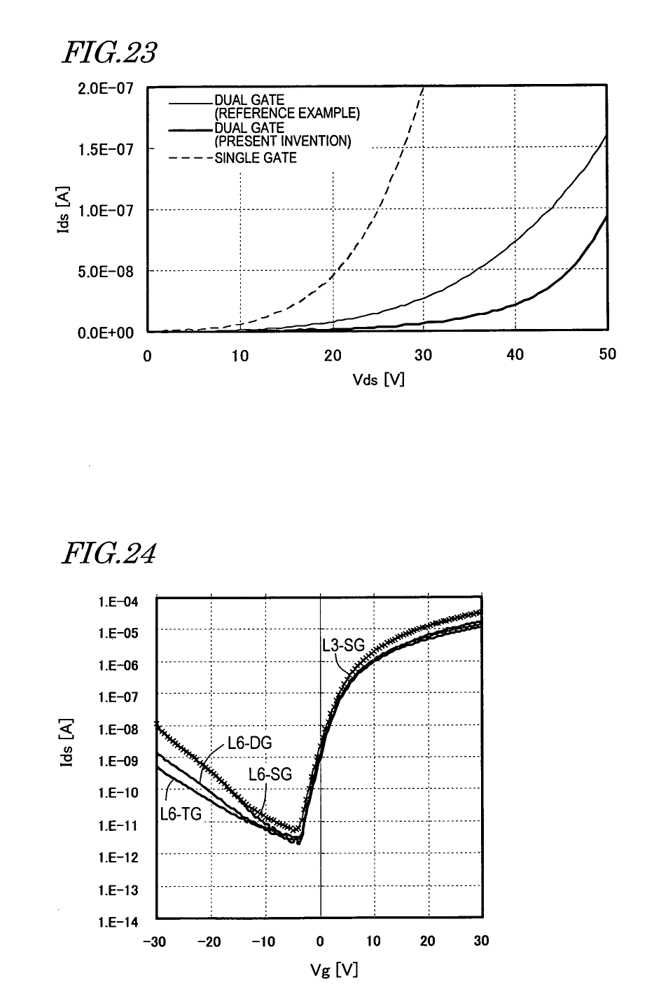

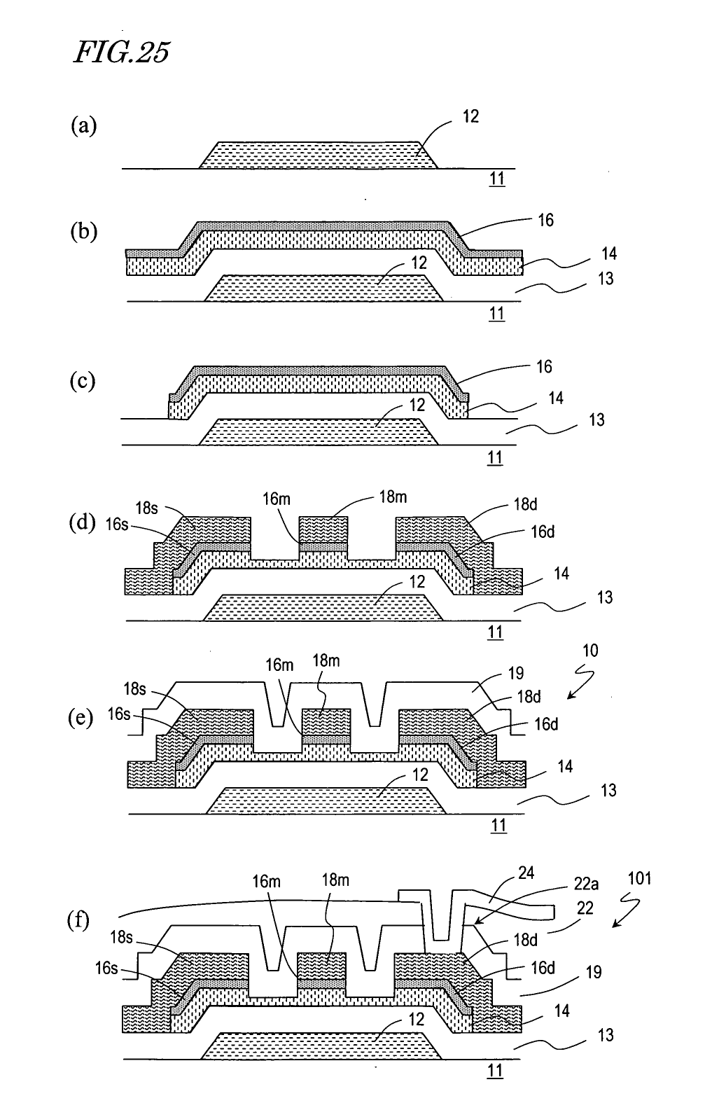

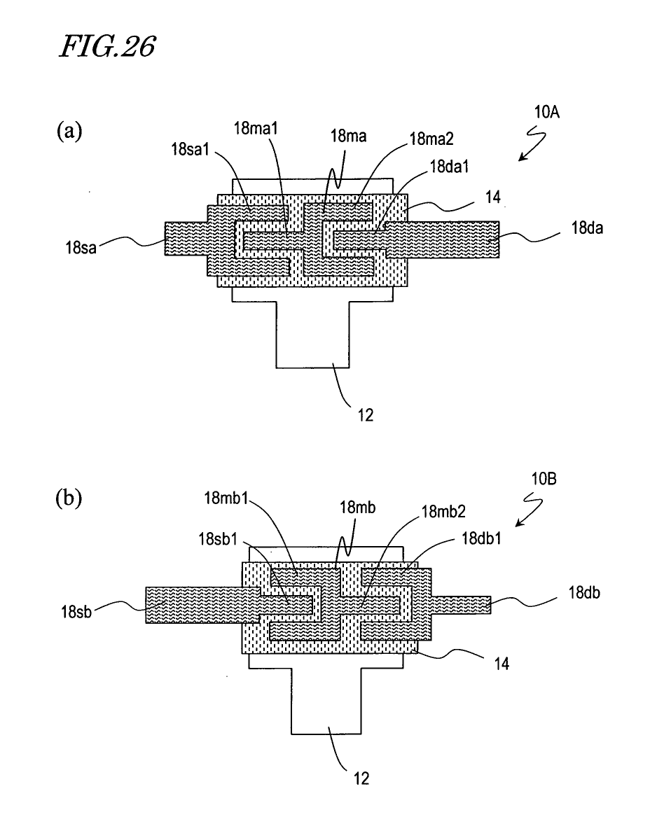

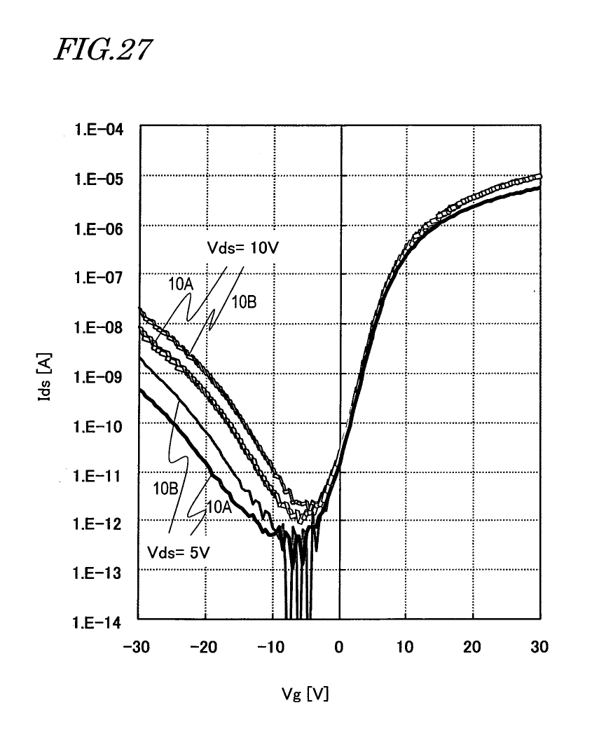

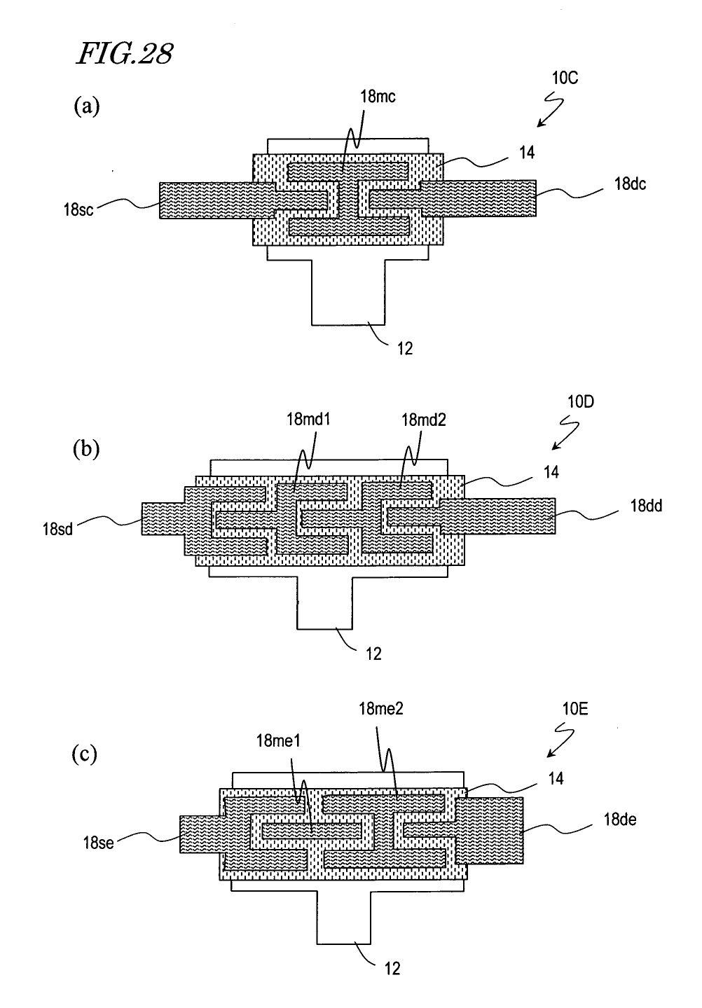

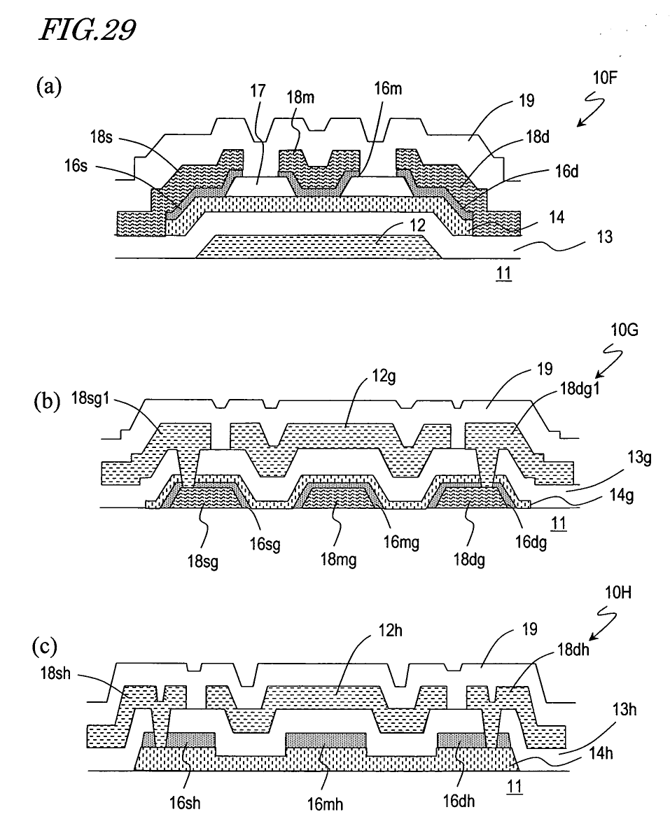

### BRIEF DESCRIPTION OF DRAWINGS

[FIG. 1](a) is a schematic plan view of a liquid crystal display panel 100 of an embodiment of the present invention, and (b) is a plan view showing a schematic structure of one pixel.

[FIG. 2] A block diagram illustrating a configuration of a shift register 110A included in a gate driver 110.

[FIG. 3] A schematic diagram showing a conventional configuration used in one stage of the shift register 110A.

[FIG. 4] A diagram showing waveforms of input/output signals at different stages of the shift register 110A and the voltage waveform of netA.

[FIG. 5] A diagram showing waveforms of output signals from four stages from n−2 to n+1 of the shift register 110A.

[FIG. 6] A circuit diagram of one stage of a shift register of an embodiment of the present invention, which is used in one stage of the shift register 110A.

[FIG. 7] Graphs illustrating problems of conventional techniques and effects of the present invention, wherein (a) is a graph showing the waveform of netA, and (b) is a graph showing the waveform of the output signal Gout.

[FIG. 8] A block diagram illustrating a configuration of another shift register 110B included in the gate driver 110.

[FIG. 9] A schematic diagram showing a conventional configuration used in one stage of the shift register 110B.

[FIG. 10] A diagram showing waveforms of input/output signals at different stages of the shift register 110B and the voltage waveform of netA.

[FIG. 11] A diagram showing waveforms of output signals from five stages from n−2 to n+2 of the shift register 110B.

[FIG. 12] A circuit diagram of one stage of a shift register of an embodiment of the present invention, which is used in one stage of the shift register 110B.

[FIG. 13](a) is a circuit diagram of one stage of another shift register of an embodiment of the present invention, and (b), (c) and (d) are diagrams showing examples of timing charts of clock signals that can be used in the shift register shown in (a).

[FIG. 14](a) is a circuit diagram of one stage of another shift register of an embodiment of the present invention, and (b) is a diagram showing an example of a timing chart of clock signals that can be used in the shift register shown in (a).

[FIG. 15] A circuit diagram of three consecutive stages of another shift register of an embodiment of the present invention.

[FIG. 16] A circuit diagram of another shift register of an embodiment of the present invention.

[FIG. 17] A circuit diagram of another shift register of an embodiment of the present invention.

[FIG. 18] A circuit diagram of another shift register of an embodiment of the present invention.

[FIG. 19] A circuit diagram showing an example of a shift register disclosed in Japanese Laid-Open Patent Publication No. 2005-50502.

[FIG. 20] A graph showing the relationship between the gate voltage Vg and the source-drain current Ids of a micro-crystalline silicon TFT having a single-channel structure.

[FIG. 21](a) is a schematic plan view of a TFT 10 of an embodiment of the present invention, (b) is a schematic cross-sectional view taken along line 21B-21B′ in (a), and (c) is an equivalent circuit diagram of the TFT 10.

[FIG. 22](a) is a schematic plan view of a conventional TFT 90 having a double-gate structure, and (b) is a schematic cross-sectional view taken along line 22B-22B′ in (a).

[FIG. 23] A graph showing examples of OFF current characteristics of the TFT 10 and the TFT 90.

[FIG. 24] A graph showing the relationship between the gate voltage Vg (V) and the source-drain current Ids (A) for TFTs having a single-channel structure, a dual-channel structure and a triple-channel structure.

[FIG. 25](a) to (f) are schematic cross-sectional views illustrating a method for manufacturing an active matrix substrate 101 including the TFT 10.

[FIG. 26](a) is a schematic plan view of a TFT 10A of an embodiment of the present invention, (b) is a schematic plan view of a TFT 10B of an embodiment of the present invention.

[FIG. 27] A graph showing the relationship between the gate voltage Vg (V) and the source-drain current Ids (A) for the TFT 10A and the TFT 10B.

[FIG. 28](a) is a schematic plan view of a TFT 10C of an embodiment of the present invention, (b) is a schematic plan view of a TFT 10D of an embodiment of the present invention, and (c) is a schematic plan view of a TFT 10E of an embodiment of the present invention.

[FIG. 29](a) is a schematic plan view of a TFT 10F of an embodiment of the present invention, (b) is a schematic plan view of a TFT 10G of an embodiment of the present invention, and (c) is a schematic plan view of a TFT 10H of an embodiment of the present invention.

### DESCRIPTION OF EMBODIMENTS

Embodiments of the shift register of the present invention will now be described with reference to the drawings. Although a shift register formed integral (monolithic) with a liquid crystal display panel will be described below as an example, the present invention is not limited to this.

FIG. 1(a) is a schematic plan view of a liquid crystal display panel 100 of an embodiment of the present invention, and FIG. 1(b) shows a schematic structure of one pixel. Note that FIG. 1(a) shows the structure of an active matrix substrate 101 of the liquid crystal display panel 100, and does not show the liquid crystal layer and the counter substrate. A liquid crystal display device is obtained by providing a backlight, a power supply, etc., in the liquid crystal display panel 100.

A gate driver 110 and a source driver 120 are formed integral with the active matrix substrate 101. A plurality of pixels are formed in the display region of the liquid crystal display panel 100, and regions of the active matrix substrate 101 corresponding to the pixels are denoted by reference numeral 132. Note that the source driver 120 does not need to be formed integral with the active matrix substrate 101. A separately made source driver IC, or the like, may be mounted by a known method.

As shown in FIG. 1(b), the active matrix substrate 101 includes a pixel electrode 101P corresponding to one pixel of the liquid crystal display panel 100. The pixel electrode 101P is connected to a source bus line 101S via a pixel TFT 101T. The gate electrode of the TFT 101T is connected to a gate bus line 101G.

An output of the gate driver 110 is connected to the gate bus line 101G, and the gate bus lines 101G are scanned in a line-sequential manner. The output of the source driver 120 is connected to the source bus line 101S, and a display signal voltage (grayscale voltage) is supplied thereto.

Next, FIG. 2 is a block diagram illustrating a configuration of a shift register 110A included in the gate driver 110. The shift register 110A is supported by an insulative substrate such as a glass substrate forming the active matrix substrate 101. TFTs forming the shift register 110A are preferably formed by the same process with the pixel TFTs 101T formed in the display region of the active matrix substrate 101.

FIG. 2 schematically shows only four stages from n−2 to n+1 of a plurality of stages of the shift register 110A. The plurality of stages have substantially the same structure, and are cascaded. The output from each stage of the shift register 110A is given to one gate bus line 101G of the liquid crystal display panel 100. Such a shift register 110A is described in Japanese Patent No. 2836642, for example. The disclosure of Japanese Patent No. 2836642 is herein incorporated by reference.

Each stage of the shift register 110A includes an input terminal S, output terminals OUT, a terminal for receiving, as a clock signal CK, one of three clock signals CK1, CK2 and CK3 whose phases are different from one another, and a terminal for receiving, as a clock signal CKB, another one of CK1, CK2 and CK3. That is, for one stage of the shift register 110A, the clock signal input as the clock signal CK and the clock signal input as the clock signal CKB are different from each other. A gate start pulse GSP is input to the input terminal S, and one output terminal OUT is connected to the corresponding gate bus line 101G while the other output terminal OUT is connected to the input terminal S of the next stage.

FIG. 3 is a schematic diagram showing a conventional configuration used in one stage of the shift register 110A, FIG. 4 shows waveforms of input/output signals and a voltage waveform of netA of each stage of the shift register 110A. FIG. 5 shows waveforms of output signals from the four stages from n−2 to n+1 of the shift register 110A. As shown in FIG. 5, the shift register 110A sequentially outputs output signals Gout from the stages.

As shown in FIG. 3, each stage of the shift register 110A includes a first transistor (TFT MA) for outputting the output signal Gout, and a plurality of second transistors (TFT ME and TFT MF) whose source region or drain region is electrically connected to the gate electrode of the first transistor TFT MA.

In the present specification, a transistor which outputs the output signal Gout is referred to as a first transistor, and a transistor whose source region or drain region is connected to the first transistor is referred to as a second transistor. In FIG. 3, the TFT MA is a so-called pull-up transistor and the TFT MB is a pull-down transistor. The line connected to the gate electrode of the TFT MA is referred to as netA, and the line connected to the gate electrode of the TFT MB is referred to as netB.

The output signal Gout is output from each stage to the gate bus line 101G only during the pixel write period. With respect to one stage, the configuration is such that the potential of the output signal Gout is fixed to VSS over most of one frame period (the period over which all the gate bus lines 101G are sequentially selected and until the subject gate bus line is selected).

By the S signal (the output signal Gout (n−1) of the preceding stage), netA is precharged, while netB is turned Low. This prevents the potential of netA precharged from leaking through a TFT MF.

Next, when the clock signal CK is High, netA is pulled up. Then, the output signal Gout(n) is output to the (n^{th}) gate bus line 101G, thus turning ON the pixel TFT 101T connected to the gate bus line 101G and supplying a display signal voltage to the pixel electrode 101P from the source bus line 101S. That is, the liquid crystal capacitor formed by the pixel electrode 101P, the counter electrode (not shown) and the liquid crystal layer (not shown) therebetween is charged.

Thereafter, the clock signal CK goes Low, thereby pulling down netA.

Then, the clock signal CKB goes High, thereby bringing netB to High, and pulling down the potentials of netA and Gout to VSS.

Note that during the period in which the output signal Gout(n) is not output, netA and the potential of Gout are fixed to VSS by the TFT MF and the TFT MB, respectively, using the clock signal CKB.

Herein, a TFT MC being ON brings netB, which is the line connected to the gate electrode of the pull-down transistor TFT MB, to High. While the TFT MC is ON, the potential of the output signal Gout is kept Low. A TFT MD brings netB to Low when the S signal is input to the gate electrode. In order to precharge netA by the S signal, leakage from the TFT MF is prevented by bringing netB to Low. VDD is a DC voltage and is the same potential as High of the clock signal CK.

If the conventional circuit shown in FIG. 4 is formed by using micro-crystalline silicon TFTs, problems as follows may occur.

When netA is pulled up, a large voltage (Vds) is applied between the source and the drain of the second transistors (a TFT ME and the TFT MF (being OFF)) whose source or drain region is connected to netA (particularly, the TFT MF). Then, the voltage of netA being pulled up lowers due to the leak current of the TFT whose source region or drain region is connected to netA before it is made to fall by the clock signal CK (Low) as intended. FIG. 7(a) shows how the waveform of netA is blunted. Reference Example in FIG. 7(a) is a case where the circuit of FIG. 3 is used.

As the voltage of netA decreases, the output signal Gout is not turned High, or the waveform of the output signal Gout is blunted, failing to supply a sufficient voltage to the pixel electrode, thus lowering the display quality. FIG. 7(b) shows how the waveform of the output signal Gout is blunted. Reference Example in FIG. 7(b) is a case where the circuit of FIG. 3 is used.

Thus, when a shift register is formed by using micro-crystalline silicon transistors, there occur problems due to leak current in the sub-threshold region of TFTs.

In the present invention, in order to solve problems described above, a multi-channel structure is employed for the TFT ME and the TFT MF which are second transistors, of the TFTs forming the shift register.

FIG. 6 shows a circuit diagram of one stage of a shift register of an embodiment of the present invention, wherein the TFT ME and the TFT MF of FIG. 3 are replaced respectively by a TFT MEd and a TFT MFd each having a dual-channel structure.

Since the TFT MEd and the TFT MFd have the dual-channel structure, the leak current in the TFT sub-threshold region is smaller than that of the conventional TFTs ME and MF having the single-channel structure, and it is possible to solve problems described above. That is, the blunting of the waveforms of netA and the output signal Gout is suppressed as shown in FIGS. 7(a) and 7(b). Note that the effect of reducing the leak current through the employment of the multi-channel structure will later be described in detail with reference to FIGS. 23 and 24.

Note that although the dual-channel structure is employed herein for all of the TFT ME and the TFT MF which are second transistors, the present invention is not limited to this, and if the dual-channel structure is employed for at least one TFT of the plurality of second transistors, the leak current can be reduced for the at least one transistor. Where the dual-channel structure is employed for some TFTs of the plurality of second transistors, it is preferred that the dual-channel structure is employed for the TFT MF of which the source-drain voltage Vds is highest. The gate electrode of the TFT MF is connected to the pull-down transistor (MB), and the source electrode or the drain electrode thereof is connected to VSS or the gate electrode (netA) of the output transistor (MA). It is understood that the multi-channel structure is preferably employed for all of the plurality of second transistors in view of the characteristics. By using a triple-channel structure rather than a dual-channel structure, it is possible to further enhance the effect of reducing the leak current. Generally, where the number of channels of a TFT having a multi-channel structure is n, the leak current can generally be made 1/n. These hold for all examples to be described below.

Next, referring to FIGS. 8-11, the configuration of another shift register 110B will be described.

FIG. 8 schematically shows only five stages from n−2 to n+2 of a plurality of stages of the shift register 110B. The plurality of stages have substantially the same structure, and are cascaded. The output from each stage of the shift register 110B is given to one gate bus line 101G of the liquid crystal display panel 100. Such a shift register 110B is described in Japanese Laid-Open Patent Publication No. 8-87893, for example. The disclosure of Japanese Laid-Open Patent Publication No. 8-87893 is herein incorporated by reference.

FIG. 9 is a schematic diagram showing a conventional configuration used in one stage of the shift register 110B, FIG. 10 shows waveforms of input/output signals and a voltage waveform of netA of each stage of the shift register 110B. FIG. 11 shows waveforms of output signals from the five stages from n−2 to n+2 of the shift register 110B. As shown in FIG. 11, the shift register 110B sequentially outputs output signals Gout from the stages.

As shown in FIG. 9, each stage of the shift register 110B includes a first transistor (TFT MG) for outputting the output signal Gout, and a plurality of second transistors (TFT MH, TFT MK, TFT MM and TFT MN) whose source region or drain region is electrically connected to the gate electrode of the first transistor TFT MG. In FIG. 9, the TFT MG is a so-called pull-up transistor, and the line connected to the gate electrode of the TFT MG is referred to as netA.

The output signal Gout is output from each stage to the gate bus line 101G only during the pixel write period. With respect to one stage, the configuration is such that the potential of Gout is fixed to VSS over most of one frame period (the period over which all the gate bus lines 101G are sequentially selected and until the subject gate bus line is selected).

By the S signal (the output signal Gout (n−1) of the preceding stage), netA is precharged. Then, the TFTs NH, MK and MN whose source region or drain region is connected to netA are OFF.

Next, when the clock signal CK is High, netA is pulled up. Then, the output signal Gout(n) is output to the (nth) gate bus line 101G, thus turning ON the pixel TFT 101T connected to the gate bus line 101G and supplying a display signal voltage to the pixel electrode 101P from the source bus line 101S. That is, the liquid crystal capacitor formed by the pixel electrode 101P, the counter electrode (not shown) and the liquid crystal layer (not shown) therebetween is charged.

Thereafter, by the reset signal R (the output signal Gout (n+1) of the following stage), the potentials of netA and Gout are pulled down to VSS.

Note that during the period in which the output signal Gout(n) is not output, netA and the potential of Gout are fixed to VSS by the TFT MK and TFT ML, respectively, using the clock signal CK and the clock signal CKB.

Herein, a capacitor CAP1 maintains the potential of netA and assists the output. A TFT MJ brings the potential of the output signal Gout to Low in response to the reset signal R. The TFT ML brings the potential of the output signal Gout to Low in response to the clock signal CKB. Once per frame (vertical scanning period), a clear signal CLR is supplied to all stages of the shift register to bring netA to Low for all stages during the vertical blanking interval (the interval from when the final stage of the shift register outputs to when the first stage outputs). Note that the clear signal CLR serves also as a reset signal for the final stage of the shift register.

If the conventional circuit shown in FIG. 9 is formed by using micro-crystalline silicon TFTs, similar problems to those described above may occur.

In the present invention, in order to solve problems described above, a multi-channel structure is employed for the TFT MH, the TFT MK, the TFT MM and the TFT MN which are second transistors, of the TFTs forming the shift register.

FIG. 12 shows a circuit diagram of one stage of a shift register of an embodiment of the present invention, wherein the TFT MH, the TFT MK, the TFT MM and the TFT MN of FIG. 9 are replaced respectively by a TFT MHd, a TFT MKd, a TFT MMd and a TFT MNd each having a dual-channel structure.

Since the TFT MHd, the TFT MKd, the TFT MMd and the TFT MNd have the dual-channel structure, the leak current in the TFT sub-threshold region is smaller than that of the conventional TFTs MH, MK, MM and MN having the single-channel structure, and it is possible to solve problems described above.

Note that although the dual-channel structure is employed herein for all of the TFT MH, the TFT MK, the TFT MM and the TFT MN which are second transistors, the present invention is not limited to this, and if the dual-channel structure is employed for at least one TFT of the plurality of second transistors, the leak current can be reduced for the at least one transistor. Where the dual-channel structure is employed for some TFTs of the plurality of second transistors, it is preferred that the dual-channel structure is employed for the TFT MB, the TFT ML and the TFT MM of which the source-drain voltage Vds is highest. The gate electrode of the TFT MB is connected to the output of the preceding stage (Gout(n−1)), and the source electrode or the drain electrode thereof is connected to the gate electrode of the output transistor TFT MG (netA) or VSS. The gate electrode of the TFT MK is connected to the line of the clock signal CK, and the source electrode or the drain electrode thereof is connected to the gate electrode of the output transistor TFT MG (netA) or VSS. The TFT MM has its gate electrode and source electrode connected to each other (diode connection), and the output (S signal) of the preceding stage is supplied to the gate electrode thereof. The drain electrode of the TFT MM is connected to the gate electrode of the TFT MG (netA). It is understood that the multi-channel structure is preferably employed for all of the plurality of second transistors in view of the characteristics.

The present invention can be used in various types of shift registers. Examples of shift registers in which the present invention can be used will be described with reference to FIGS. 13-19.

FIG. 13(a) shows a circuit diagram of one stage of another shift register of an embodiment of the present invention. This shift register is formed by cascading together a plurality of stages each having substantially the same circuit as that shown in FIG. 13(a). FIG. 13(b), 13(c) or 13(d) shows an example of a timing chart of clock signals that can be used in the shift register shown in FIG. 13(a). These are obtained by applying the present invention to shift registers described in Japanese Patent Application No. 2008-037625 and Japanese Patent Application No. 2008-068279. The disclosure of these applications is herein entirely incorporated by reference.

In FIG. 13(a), a TFT M1 is the first transistor, and a TFT M2d and a TFT M3d which are the second transistors have the dual-channel structure. Therefore, this shift register can also solve problems described above.

Herein, the source electrode or the drain electrode of the TFT M1 is connected to the line of the clock signal (CKA) or the gate bus line for outputting the output signal Gout. The source electrode or the drain electrode of the TFT M2d is connected to the gate electrode of the TFT M1 or VSS, and the gate electrode of the TFT M2d is connected to the output (Qn+1) of the following stage. The TFT M2d brings netA to Low at the reset timing. The drain electrode of the TFT M3d is connected to the gate electrode of the TFT M1. The output (Qn−1) of the preceding stage is input to the source electrode and the gate electrode of the TFT M3d which are connected in diode connection. The gate electrode of a TFT M4 is connected to the line of the clock signal (CKB), and the source electrode or the drain electrode is connected to the gate bus line (Gout) or VSS. The TFT M4 serves to prevent potential fluctuation of the output signal Gout when not selected. A capacitor C1 is a capacitor for assisting the output, and prevents the potential of netA from lowering when selected.

FIG. 14(a) shows a circuit diagram of one stage of another shift register of an embodiment of the present invention. FIG. 14(b) shows an example of a timing chart of clock signals that can be used in the shift register shown in FIG. 14(a).

In FIG. 14(a), a TFT M5 is the first transistor, and a TFT M8d and a TFT M9d which are the second transistors have the dual-channel structure. Therefore, this shift register can also solve problems described above.

Here, the source electrode or the drain electrode of the TFT M5 is connected to the line of the clock signal (CKA) or the gate bus line (Gout). The source electrode or the drain electrode of the TFT M8d is connected to the gate electrode of the TFT M5 or VSS. The gate electrode of the TFT M8d is connected to the output (Qₙ₊₁) of the following stage, and brings netA to Low at the reset timing. The drain electrode of the TFT M9d is connected to the gate electrode of the TFT M5, and the output signal (Qₙ₋₁) of the preceding stage is input to the source electrode and the gate electrode of the TFT M9d which are connected in diode connection. The source electrode or the drain electrode of TFTs M6, M7 and M10 is connected to the gate bus line (Gout) or VSS, and the gate electrodes thereof are connected to lines of clock signals whose phases are different from one another. A capacitor C2 is a capacitor for assisting the output, and prevents the potential of netA from lowering when selected.

As shown in the timing chart of FIG. 14(b), since the duty of the clock is ¼, it is possible to keep Gout Low with a duty of ¾ when not outputting while preventing deterioration of the TFT.

FIG. 15 shows a circuit diagram of consecutive three stages of another shift register of an embodiment of the present invention.

In FIG. 15, a TFT M11 is the first transistor, and a TFT M12d and a TFT M13d which are the second transistors have the dual-channel structure. Therefore, this shift register can also solve problems described above.

The source electrode or the drain electrode of the TFT M11 is connected to the line of the clock signal (CK1) or the gate bus line (OUT1, 2 or 3). The source electrode or the drain electrode of the TFT M13d is connected to the gate electrode of the TFT M11 or VSS. The gate electrode of the TFT M13d is connected to the output of the following stage (the output of the TFT M11 of the following stage). The TFT M13d brings netA to Low at the reset timing. The drain electrode of the TFT M12d is connected to the gate electrode of the TFT M11, and the output of the preceding stage (the output signal of the TFT M11 of the preceding stage) is input to the source electrode and the gate electrode of the TFT M12d which are connected in diode connection.

Note that the shift registers shown in FIGS. 14 and 15 are those obtained by applying the present invention to the shift register described in Japanese Patent Application No. 2008-068279.

FIGS. 16-18 show circuit diagrams of other shift registers according to embodiments of the present invention. These are obtained by applying the present invention to the shift register described in Japanese Patent Application No. 2008-037626. The disclosure of this publication is herein entirely incorporated by reference.

In FIG. 16, a TFT M15 is the first transistor, and a TFT M16d, a TFT M19d, a TFT M21d and a TFT M22d which are the second transistors have the dual-channel structure. Therefore, this shift register can also solve problems described above.

The source electrode or the drain electrode of the TFT M15 is connected to the line of the clock signal (CKA) or the gate bus line (Gout₍ₙ₎). The source electrode or the drain electrode of the TFT M16d is connected to the gate electrode of the TFT M15 or VSS. The gate electrode of the TFT M16d is connected to the output (Gout₍ₙ₊₁₎) of the following stage. The TFT M16d brings netA to Low at the reset timing. The gate electrode of the TFT M21d is connected to the TFT M15, and the output (Gout₍ₙ₋₁₎) of the preceding stage is input to the source electrode and the gate electrode of the TFT M21d which are connected in diode connection. The source electrode or the drain electrode of the TFT M19d is connected to the gate electrode of the TFT M15 or the gate bus line (Gout₍ₙ₎), and the gate electrode of the TFT M19d is connected to the line of the clock signal (CKA). The source electrode or the drain electrode of the TFT M22d is connected to the gate electrode of the TFT M15 or VSS, and the clear signal CLR is input to the gate electrode of the TFT M22d. Once per frame (vertical scanning period), a clear signal CLR is supplied to all stages of the shift register to bring netA to Low for all stages during the vertical blanking interval (the interval from when the final stage of the shift register outputs to when the first stage outputs). Note that the clear signal CLR serves also as a reset signal for the final stage of the shift register. The source electrode or the drain electrode of a TFT M17 is connected to the gate bus line (Gout₍ₙ₎) or VSS, and the gate electrode thereof is connected to the output (Gout₍ₙ₋₁₎) of the following stage. The source electrode or the drain electrode of a TFT M18 and a TFT M20 is connected to the gate bus line (Gout₍ₙ₎) or VSS, and the gate electrodes thereof are connected to lines of clock signals whose phases are different from each other.

The shift register shown in FIG. 17 is different from the shift register shown in FIG. 16 for points to be described below, and is the same as otherwise.

The drain electrode of the TFT M21d is connected to the gate electrode of the TFT M15. The output (Gout₍ₙ₋₂₎) of the stage before the preceding stage is input to the source electrode and the gate electrode of the TFT M21d which are connected in diode connection. The source electrode or the drain electrode of the TFT M18 and the TFT M20 is connected to the gate bus line (Gout₍ₙ₎) or VSS, and the gate electrodes thereof are connected to lines of clock signals whose phases are equal to each other.

In FIG. 17, the TFT M15 is the first transistor, and the TFT M16d, the TFT M19d, the TFT M21d and the TFT M22d which are the second transistors have the dual-channel structure. Therefore, these shift registers can also solve problems described above.

Note that the circuit shown in FIG. 17 uses a common clock signal CKB for the transistors TFT M20 and TFT M18, omitting the clock signal CKC, as opposed to the circuit shown in FIG. 16 which uses three clock signals CKA, CKB and CKC having different phases. The circuit shown in FIG. 17 uses the output signal Gout₍ₙ₋₂₎ of the stage before the preceding stage for the TFT M21d.

The present invention can also be applied to the shift register disclosed in Japanese National Phase PCT Laid-Open Publication No. 10-500243. The disclosure of this publication is herein entirely incorporated by reference. FIG. 18 shows a configuration of a shift register obtained by applying the present invention to the shift register disclosed in this publication. In FIG. 18, a TFT M23 is the first transistor, and a TFT M24d and a TFT M25d which are the second transistors have the dual-channel structure. Therefore, these shift registers can also solve problems described above.

The source electrode or the drain electrode of the TFT M23 is connected to the line of the clock signal Φ1 or the gate bus line (Gout₍ₙ₎). The gate electrode of the TFT M23 is connected to the node to be bootstrapped (netA in FIG. 17, the node G in FIG. 18). The TFT M24d charges the node G. The source electrode and the gate electrode of the TFT M24d are connected in diode connection, and connected to the output signal Gout₍ₙ₋₁₎ of the preceding stage or the node G. The TFT M25d discharges the node G. The source electrode or the drain electrode of the TFT M25d is connected to the node G or VSS (DC), and the gate electrode of the TFT M25d is connected to the line of the output signal Gout₍ₙ₊₁₎ of the following stage. A capacitor C4 shows a parasitic capacitor. A capacitor C6 prevents fluctuation of the node G when not selected. One end of the capacitor C6 is connected to the node G, and the clock signal Φ2 is input to the other end thereof. The clock signal Φ2 is a clock signal having a reversed phase from the clock signal Φ1. The clock signals Φ1 and Φ2 correspond to the clock signals CKA and CKB, respectively, of FIG. 17. A capacitor C5 assists the output (prevents the output from weakening due to the capacitor C6).

Moreover, the present invention can also be applied to the shift register disclosed in Japanese Laid-Open Patent Publication No. 2005-50502. The disclosure of this publication is herein entirely incorporated by reference.

For example, in FIG. 19 disclosed in this publication, the TFT Q2 is the first transistor, and the TFT Q5 which is the second transistor can be changed to a multi-channel structure, thereby obtaining the effects of the present invention.

The source electrode or the drain electrode of the TFT Q2 is connected to the line of the clock signal (CK) or the gate bus line (OUT). The drain electrode of the TFT Q1 is connected to the gate electrode of the TFT Q2. The output signal of the preceding stage, for example, is input as the input signal to the source electrode and the gate electrode of the TFT Q1 which are connected in diode connection. The source electrode or the drain electrode of the TFT Q5 is connected to the gate electrode of the TFT Q2 or the gate bus line (OUT), and the gate electrode of the TFT Q5 is connected to the line of the clock signal (CK). The source electrode or the drain electrode of the TFT Q4 is connected to the gate electrode of the TFT Q2 or VOFF (DC), and the output signal of the following stage, for example, is input as the input signal to the gate electrode of the TFT Q4. The source electrode or the drain electrode of the TFT Q3 is connected to the gate bus line (OUT) or VOFF (DC), and the output signal of the following stage, for example, is input as the input signal to the gate electrode of the TFT Q3.

While multi-channel TFTs to be used in the shift register described above may be those disclosed in Patent Document No. 3 or 4, etc., it is preferred to use multi-channel TFTs to be described below of an embodiment of the present invention.

[Multi-Channel TFT]

Embodiments of the semiconductor device of the present invention will now be described with reference to the drawings. Although a TFT including a micro-crystalline silicon film as the active layer will be described hereinbelow as an example, the present invention is not limited to this.

FIG. 21 schematically shows a TFT 10 of an embodiment of the present invention. FIG. 21(a) is a schematic plan view of the TFT 10, FIG. 21(b) is a schematic cross section taken along line 21B-21B′ in FIG. 21(a), and FIG. 21(c) is an equivalent circuit diagram of the TFT 10.

The TFT 10 has a dual-channel structure, and has a structure that is electrically equivalent to two TFTs connected in series as shown in the equivalent circuit diagram of FIG. 21(c).

The TFT 10 includes an active layer 14 supported by a substrate (e.g., a glass substrate) 11. The active layer 14 is a semiconductor layer, and herein includes a micro-crystalline silicon film. The active layer 14 includes channel regions 14c1 and 14c2, a source region 14s, a drain region 14d, and an intermediate region 14m formed between the two channel regions 14c1 and 14c2. Although an example where there are one intermediate region 14m and two channel regions 14c1 and 14c2 is illustrated herein, the present invention is not limited to this, and there may be two or more intermediate regions and three or more channel regions.

The TFT 10 further includes: a contact layer 16 including a source contact region 16s in contact with the source region 14s, a drain contact region 16d in contact with the drain region 14d, and an intermediate contact region 16m in contact with the intermediate region 14m; a source electrode 18s in contact with the source contact region 16s, a drain electrode 18d in contact with the drain contact region 16d, and an intermediate electrode 18m in contact with the intermediate contact region 16m; and a gate electrode 12 opposing the two channel regions 14c1 and 14c2 and the intermediate region 14m with a gate insulating film 13 interposed therebetween. The intermediate electrode 18m is a so-called floating electrode which does not form an electric connection anywhere. The TFT 10 further includes a protection film 19 covering these.

The first channel region 14c1 is formed between the source region 14s and the intermediate region 14m, and the second channel region 14c2 is formed between the drain region 14d and the intermediate region 14m. The two channel regions 14c1 and 14c2, the source region 14s, the drain region 14d, and the intermediate region 14m are all formed in a single continuous active layer 14. The entirety of a portion of the intermediate electrode 18m that is present between the first channel region 14c1 and the second channel region 14c2 overlaps with the gate electrode 12 with the intermediate region 14m and the gate insulating film 13 interposed therebetween.

Although the entirety of the intermediate electrode 18m herein overlaps with the gate electrode 12 with the intermediate region 14m and the gate insulating film 13 interposed therebetween, the present invention is not limited to this. For example, where the intermediate electrode 18m is provided so as to extend to the outside of the region between the first channel region 14c1 and the second channel region 14c2 which are located on opposite sides thereof, e.g., where it extends in the up-down direction in FIG. 21(a), the portion that is present outside of the region between the first channel region 14c1 and the second channel region 14c2 does not need to overlap with the gate electrode 12 with the intermediate region 14m and the gate insulating film 13 interposed therebetween.

The TFT 10 differs from the TFT described in Patent Document Nos. 3 and 4 (TFT 90 shown in FIG. 22 as Reference Example) in that the entirety of the portion of the intermediate electrode 18m that is present between the first channel region 14c1 and the second channel region 14c2 overlaps with the gate electrode 12 with the intermediate region 14m and the gate insulating film 13 interposed therebetween, and has advantages such as having a superior effect of reducing the OFF current.

Note that as is clear from the cross-sectional structure shown in FIG. 21(b), the TFT 10 is of the bottom gate type (reverse staggered type) in which the gate electrode 12 is provided between the active layer 14 and the substrate 11, and is of the channel-etched type in which the channel regions 14c1 and 14c2 are formed in regions where the active layer 14 is etched.

The active layer 14 of the TFT 10 is formed by a micro-crystalline silicon film or a layered film of a micro-crystalline silicon film and an amorphous silicon film, and can be manufactured using a conventional process for manufacturing an amorphous silicon TFT. A micro-crystalline silicon film can be formed by using a plasma CVD method similar to a method of making an amorphous silicon film using a silane gas diluted with a hydrogen gas as the material gas, for example.

A micro-crystalline silicon film will now be described in detail.

A micro-crystalline silicon film has a structure in which the crystalline silicon phase and the amorphous silicon phase are mixed. The volume percentage of the amorphous phase in the micro-crystalline silicon film can be controlled in the range of 5% or more and 95% or less, for example. Note that the volume percentage of the amorphous phase is preferably 5% or more and 40% or less, and it is possible to thereby effectively improve the ON/OFF ratio of the TFT. When Raman scattered spectroscopy using visible light is performed on a micro-crystalline silicon film, the spectrum has the highest peak at the wavelength of 520 cm⁻¹, which is the peak of crystalline silicon, and has a broad peak at the wavelength of 480 cm⁻¹, which is the peak of amorphous silicon. The peak height of amorphous silicon in the vicinity of 480 cm⁻¹ is 1/30 or more and 1 or less, for example, of the peak height of crystalline silicon seen in the vicinity of 520 cm⁻¹.

For the purpose of comparison, when Raman scattered spectroscopy is performed on a polycrystalline silicon film, hardly any amorphous component is observed with the peak height for amorphous silicon being substantially zero. Note that there are cases where the amorphous phase remains locally depending on crystallization conditions when forming the polycrystalline silicon film, but even in such cases, the volume percentage of the amorphous phase in the polycrystalline silicon film is generally less than 5%, with the peak height for amorphous silicon by Raman scattered spectroscopy being generally less than 1/30 of the peak height for polycrystalline silicon.

A micro-crystalline silicon film includes crystal particles and amorphous phase. A thin amorphous layer (hereinafter referred to as an “incubation layer”) may be formed on the substrate side of the micro-crystalline silicon film. The thickness of the incubation layer is some nm, for example, though it depends on the deposition conditions of the micro-crystalline silicon film. Note however that there are cases where substantially no incubation layer is observed depending on the deposition conditions and the deposition method of the micro-crystalline silicon film, e.g., particularly, cases where high-density plasma CVD is used.

Crystal particles included in a micro-crystalline silicon film are typically smaller than crystal particles forming a polycrystalline silicon film. Observing a cross section of a micro-crystalline silicon film using a transmission electron microscope (TEM) shows that the average particle diameter of the crystal particles is generally 2 nm or more and 300 nm or less. Crystal particles may be in such a form that it extends in a columnar shape from the incubation layer to the upper surface of the micro-crystalline silicon film. When the diameter of the crystal particles is about 10 nm and when the volume percentage of the crystal particles with respect to the entire micro-crystalline silicon film is 60% or more and 85% or less, it is possible to obtain a high-quality micro-crystalline silicon film with few defects in the film.

Micro-crystalline silicon includes crystal particles and therefore has a higher carrier mobility than amorphous silicon but has a smaller bandgap and is likely to have defects formed in the film as compared with amorphous silicon. Therefore, a micro-crystalline silicon TFT has a problem that the OFF current is large. With the TFT 10 of an embodiment of the present invention, the OFF current of the TFT can be reduced by the novel multi-gate structure.

A structure of a TFT 90 of Reference Example will now be described with reference to FIG. 22. FIG. 22 is a schematic diagram of the TFT 90 having a double-gate structure described in Patent Document Nos. 3 and 4, wherein FIG. 22(a) is a schematic plan view, and FIG. 22(b) is a schematic cross-sectional view taken along line 22B-22B′ in FIG. 22(a).

A gate electrode 92 of the TFT 90 is branched into two, and has two gate branch portions 92a and 92b. Active layers 94a and 94b corresponding respectively to the two gate branch portions 92a and 92b are formed separately with a gate insulating film 93 which covers the gate electrode 92 interposed therebetween. The active layer 94a includes a source region 94s, a first channel region 94c1 and a first intermediate region 94ma formed therein, and the active layer 94b includes a drain region 94d, a second channel region 94c2 and a second intermediate region 94mb formed therein. A source electrode 98s is formed so as to oppose the source region 94s with a source contact layer 96s interposed therebetween, and a drain electrode 98d is formed so as to oppose the drain region 94d with a drain contact layer 96d interposed therebetween. The TFT 90 further includes a protection film 99 covering these.

An intermediate electrode 98m of the TFT 90 is formed so as to oppose the intermediate region 94ma with an intermediate contact layer 96ma interposed therebetween and oppose the intermediate region 94mb with an intermediate contact layer 96mb interposed therebetween. The intermediate electrode 98m is formed so as to bridge between the two active layers 94a and 94b and between two gate branch portions 92a and 92b, and the portion of the intermediate electrode 98m that is present between the first channel region 94c1 and the second channel region 94c2 includes a portion that does not overlap with any of the active layers 94a and 94b and the gate electrode 92.

Although the equivalent circuit of the TFT 90 is the same as the equivalent circuit of the TFT 10 shown in FIG. 21(c), the TFT 10 has the following advantages over the TFT 90 because of the difference in the configuration of the intermediate electrode and the active layer.

First, the TFT 10 can reduce the OFF current more than the TFT 90. The reason will be described below.

As shown in FIGS. 22(a) and 22(b), in the TFT 90, only the opposite end portions of the intermediate electrode 98m are electrically connected to the active layers 94a and 94b with the intermediate contact layers 96ma and 96mb interposed therebetween. Therefore, in the TFT 90, one end (on the side of the intermediate contact layer 96ma) of the intermediate electrode 98m serves as a drain electrode for the source electrode 98s, and the other end (on the side of the intermediate contact layer 96mb) of the intermediate electrode 98m serves as a source electrode for the drain electrode 98d. Thus, an electric field localizes in the opposite end portions of the intermediate electrode 98m.

In contrast, as shown in FIGS. 21(a) and 21(b), in the TFT 10, the entirety of the intermediate electrode 18m is electrically connected to the active layer 14 with the intermediate contact layer 16m interposed therebetween. Therefore, the intermediate electrode 18m itself serves as a drain electrode for the source electrode 18s and also serves as a source electrode for the drain electrode 18d. Thus, the degree of electric field localization in the intermediate electrode 18m of the TFT 10 is mitigated as compared with the degree of electric field localization in the opposite end portions of the intermediate electrode 98m of the TFT 90. As a result, the OFF current of the TFT 10 is even smaller than the OFF current of the TFT 90, and the reliability of the TFT 10 is greater than the reliability of the TFT 90.

FIG. 23 shows examples of the OFF current characteristics of the TFT 10 and the TFT 90. FIG. 23 also shows the OFF current characteristics of a TFT having a single-channel structure. The horizontal axis of FIG. 23 is the source-drain voltage Vds (V), and the vertical axis thereof is the source-drain current Ids (A). Here, the gate voltage is 0 V, and Ids denotes the OFF current. Note that the semiconductor layers of the TFT 10 and the TFT 90 used herein are micro-crystalline silicon films formed by a high-density PECVD method. The degree of crystallinity of the micro-crystalline silicon film is about 70% as measured by Raman spectroscopy, and the particle diameter is about 5 nm to about 10 nm. The channel length (L) and the channel width (W) of the TFT are L/W=4 μm/100 μm.

As is clear from FIG. 23, a TFT (Reference Example) having a conventional dual-channel structure has a smaller OFF current than a single-channel structure TFT, and a TFT having a novel dual-channel structure of the present invention has an even smaller OFF current. With the dual-channel structure of the present invention, the electric field localization in the intermediate electrode is mitigated, and it is therefore possible to reduce the OFF current particularly when a high electric field is applied.

Next, referring to FIG. 24, the relationship between the gate voltage Vg (V) and the source-drain current Ids (A) will be described for TFTs having a single-channel structure, a dual-channel structure and a triple-channel structure. The horizontal axis of FIG. 24 is the gate voltage Vg (V), and the vertical axis thereof is the source-drain current Ids (A). The source-drain voltage Vds is 10 V.

Here, the dual-channel structure is a structure similar to that of the TFT 10 shown in FIG. 21, the single-channel structure is a structure of the TFT 10 without the intermediate electrode 18m, and the triple-channel structure is a structure obtained by arranging two intermediate electrodes 18m of the TFT 10 in parallel to each other. The channel lengths are all 6 μm. That is, the single-channel structure has a single channel having a channel length of 6 μm (L6-SG), the dual-channel structure has two channels each having a channel length of 3 μm (L6-DG), and the triple-channel structure has three channels each having a channel length of 2 μm (L6-TG). Note that FIG. 24 also shows results (L3-SG) for a single-channel structure having a channel length of 3 μm.

First, observing results of FIG. 24 for the single-channel structures, no difference in OFF current is seen between a case where the channel length is 6 μm (L6-SG) and a case where the channel length is 3 μm (L3-SG). That is, it can be seen that there is no correlation between the magnitude of the OFF current and the channel length, and the OFF current is exclusively the leak current in the drain portion.

As is clear from FIG. 24, it can be seen that it is possible to reduce the OFF current by employing a dual-channel structure and a triple-channel structure. It can also be seen that the effect of reducing the OFF current is greater with the triple-channel structure than with the dual-channel structure.

Table 1 below shows values of source-drain OFF current for a case where the gate voltage is 0 V and the source-drain voltage Vds is 40 V and those for a case where the gate voltage is −29 V and the source-drain voltage Vds is 10 V.

TABLE 1

| | OFF current (A) | | |
|---|---|---|---|
| Vg/Vds | Single channel | Dual channel | Triple channel |
| 0 V/40 V | 3.0 × E−09 | 1.9 × E−10 | 6.0 × E−11 |
| −29 V/10 V | 6.6 × E−09 | 1.0 × E−09 | 3.9 × E−10 |

As can be seen from the results of Table 1, where Vds is 40 V, the OFF current when the gate voltage Vg is 0 V can be reduced by one or two orders of magnitude by employing a dual-channel structure or a triple-channel structure, as compared with a single-channel structure. On the other hand, where Vds is 10 V, the OFF current when the gate voltage Vg is −29 V can be reduced by about one order of magnitude by employing a dual-channel structure or a triple-channel structure, as compared with a single-channel structure.

As described above, it can be seen that the OFF current of a TFT can be effectively reduced by employing a multi-channel structure of the present invention. That is, with the present invention, it is possible to reduce the leak current in the OFF region as well as the leak current in the sub-threshold region of a TFT. Therefore, by forming a shift register using TFTs of the present invention, it is possible to improve the characteristics of the shift register. By using TFTs of the present invention as pixel TFTs, as described in Patent Document No. 3 or 4, it is possible to improve the voltage retention characteristics of pixels.

Employing a multi-channel structure of the present invention provides an advantage that a TFT can be made smaller than a TFT having a conventional multi-channel structure.

Reference is made again to FIGS. 21(a) and 22(a). As is clear from a comparison between FIG. 21(a) and FIG. 22(a), the length of the TFT 10 in the channel direction is smaller than that of the TFT 90.

The length of the TFT 10 in the channel direction (the direction from the source electrode 18s to the drain electrode 18d) is given as 2L1+2L2+L3, as can be seen from FIG. 21(a). Now, L1 is the length of the region over which the source electrode 18s overlaps with the gate electrode 12 with the active layer 14 interposed therebetween or the length of the region over which the drain electrode 18d overlaps with the gate electrode 12 with the active layer 14 interposed therebetween. L2 is the length of each of the channel regions 14c1 and 14c2. L3 is the length of the intermediate electrode 18m. For example, assuming that L1=3 μm, L2=4 μm and L3=4 μm, the length of the TFT 10 in the channel direction is 2L1+2L2+L3=18 μm.

In contrast, the length of the TFT 90 in the channel direction (the direction from the source electrode 98s to the drain electrode 98d) is given as 2L1+2L2+2L4+L5, as can be seen from FIG. 22(a). Now, L1 is the length of the region over which the source electrode 98s overlaps with the gate branch portion 92a with the active layer 94a interposed therebetween or the length of the region over which the drain electrode 98d overlaps with the gate branch portion 92b with the active layer 94b interposed therebetween. L2 is the length of each of the channel regions 94c1 and 94c2. L4 is the length of the region over which the intermediate electrode 98m overlaps with the gate branch portion 92a with the active layer 94a interposed therebetween or the length of the region over which the intermediate electrode 98m overlaps with the gate branch portion 92b with the active layer 94b interposed therebetween. For example, assuming that L1=3 μm, L2=4 μm, L4=3 μm and L5=5 μm, the length of the TFT 90 in the channel direction is 2L1+2L2+2L4+L5=25 μm.

Thus, by employing the novel dual-channel structure of the present invention, TFTs can be made smaller.

Next, referring to FIGS. 25(a) to 25(f), a method for manufacturing the active matrix substrate 101 having the TFTs 10 will be described. The active matrix substrate 101 illustrated herein is used in a liquid crystal display device.

First, as shown in FIG. 25(a), the gate electrode 12 is formed on the glass substrate 11. The gate electrode 12 is formed by, for example, patterning a Ti/Al/Ti layered film (a thickness of 0.2 μm, for example). In this process, the gate bus lines and CS bus lines (both not shown) can be formed by using the same conductive film as the gate electrode 12.

Next, as shown in FIG. 25(b), the gate insulating film 13, a micro-crystalline silicon film 14 and an N⁺ silicon film 16 are consecutively deposited in this order. The gate insulating film 13 is formed by, for example, depositing an SiNₓ film (a thickness of 0.4 μm, for example) 13 by a parallel plate-type plasma CVD method. The micro-crystalline silicon film (a thickness of 0.12 μm, for example) 14 is formed by a high-density plasma CVD method. The N⁺ silicon film (a thickness of 0.05 μm, for example) 16 is formed by a high-density plasma CVD method or a parallel plate-type plasma CVD method.

The deposition of the SiNₓ film 13 is performed under conditions including a substrate temperature: 300° C., a pressure: 50-300 Pa and a power density: 10-20 mW/cm², using a deposition chamber having a parallel plate (capacitive coupling) electrode structure, for example. A mixed gas of silane (SiH₄), ammonium (NH₃) and nitrogen (N₂) is used as the gas for deposition.

The deposition of the micro-crystalline silicon film 14 is performed under conditions including a substrate temperature: 250-350° C., a pressure: 0.5-5 Pa and a power density: 100-200 mW/cm², using an ICP-type high-density PECVD, and a silane gas diluted with a hydrogen gas is used as the gas for deposition. The flow rate between silane (SiH₄) and hydrogen (H₂) is set to 1:1-1:10.

The deposition of the N⁺ silicon film 16 is performed under conditions including a substrate temperature: 250-300° C., a pressure: 50-300 Pa and a power density: 10-20 mW/cm² using a deposition chamber having a parallel plate (capacitive coupling) electrode structure. A mixed gas of silane (SiH₄), hydrogen (H₂) and phosphine (PH₃) is used as the gas for deposition.

Thereafter, the micro-crystalline silicon film 14 and the N⁺ silicon film 16 are patterned, thereby obtaining the active layer 14 and the contact layer 16, as shown in FIG. 25(c).

Next, as shown in FIG. 25(d), a metal film (so-called a source metal) is deposited so as to cover the N⁺ silicon film 16 and patterned, thereby forming the source electrode 18s, the drain electrode 18d and the intermediate electrode 18m. An Al/Mo layered film may be used as the metal film, for example. The patterning of the Al/Mo film can be performed by using an SLA etchant (H₃PO₄:H₂O:HNO₃:CH₃COOH=16:2:1:1) which is a common metal etchant.

By etching the contact layer (N⁺ silicon film) 16 by a dry etching method using a mask (e.g., a photoresist layer) which is used for etching the metal film, it is divided into the source contact region 16s, the drain contact region 16d and the intermediate contact region 16m. In this process, a portion of the active layer (micro-crystalline silicon film) 14 is also etched (channel etching). The remaining film thickness of the active layer 14 is about 40 nm.

Next, as shown in FIG. 25(e), the protection film 19 is formed. For example, an SiNₓ film deposited by plasma CVD may be used as the protection film 19. Thus, the TFT 10 is obtained.

Moreover, as shown in FIG. 25(f), a planarization film 22 is formed. The planarization film 22 is formed by using an organic resin film, for example. A contact hole 22a is formed in the planarization film 22 and the protection film 19. Thereafter, a transparent conductive film (e.g., an ITO film) is deposited and patterned, thereby forming a pixel electrode 24. The pixel electrode 24 is connected to the drain electrode 18d in the contact hole 22a.

The active matrix substrate 101 having the TFT 10 connected to the pixel electrode 24 is obtained as described above.

Next, referring to FIGS. 26 and 27, a structure of another TFT of an embodiment of the present invention will be described.

FIG. 26(a) is a schematic plan view of a TFT 10A, and FIG. 26(b) is a schematic plan view of a TFT 10B. The cross-sectional structures of the TFT 10A and the TFT 10B are the same as the cross-sectional structure of the TFT 10 shown in FIG. 21(b), and therefore will be omitted.

The TFT 10A shown in FIG. 26(a) has a dual-channel structure similar to that of the TFT 10 shown in FIG. 21. The TFT 10A includes the gate electrode 12, the active layer 14, a source electrode 18sa, a drain electrode 18da, and an intermediate electrode 18ma, formed on a substrate (not shown). A contact layer (not shown) is formed between each of the electrodes 18sa, 18da and 18ma and the active layer 14. The region over which the active layer 14 overlaps with the source electrode 18sa with the contact layer interposed therebetween is the source region, the region over which the active layer 14 overlaps with the drain electrode 18da with the contact layer interposed therebetween is the drain region, and the region over which the active layer 14 overlaps with the intermediate electrode 18ma with the contact layer interposed therebetween is the intermediate region. As seen in a direction vertical to the substrate, the source region has the same shape as the source electrode 18sa, the drain region has the same shape as the drain electrode 18da, and the intermediate region has the same shape as the intermediate electrode 18ma.

A feature of the TFT 10A is that the area of the portion of the gate electrode 12 that overlaps with the drain region is smaller than the area of the portion of the gate electrode 12 that overlaps with the source region.

As shown in FIG. 26(a), the intermediate electrode 18ma includes a depressed portion 18ma2, and the drain electrode 18da includes a protruding portion 18da1 in the depressed portion 18ma2 of the intermediate electrode 18ma. The portion of the drain electrode 18da that overlaps with the gate electrode 12 with the active layer 14 (i.e., a drain region) interposed therebetween is the portion 18da1 which is protruding in a narrow shape from the main body. As is clear from a comparison with the drain electrode 18d of the TFT 10 shown in FIG. 21(a), the area of the portion of the drain electrode 18da of the TFT 10A that overlaps with the gate electrode 12 with the active layer 14 interposed therebetween is small.

In the TFT 10A shown in FIG. 26(a), the source electrode 18sa includes a depressed portion 18sa1, and the intermediate electrode 18ma includes a protruding portion 18ma1 in the depressed portion 18sa1 of the source electrode 18sa. As is clear from a comparison with the source electrode 18s of the TFT 10 shown in FIG. 21(a), the area of the portion of the source electrode 18sa of the TFT 10A that overlaps with the gate electrode 12 with the active layer 14 interposed therebetween is large.

Thus, since the drain electrode 18da, the intermediate electrode 18ma and the source electrode 18sa of the TFT 10A shown in FIG. 26(a) have such shapes as described above, the area of the portion of the gate electrode 12 that overlaps with the drain region is smaller than the area of the portion of the gate electrode 12 that overlaps with the source region. The area of the portion of the gate electrode 12 that overlaps with the drain region is smaller than the area of the portion of the gate electrode 12 that overlaps with the intermediate region.

Note that even if the configuration on the left side of the intermediate electrode 18ma of the TFT 10A in FIG. 26(a) is made to be the same as the configuration on the left side of the intermediate electrode 18m of the TFT 10 shown in FIG. 21(a), the area of the portion of the gate electrode 12 that overlaps with the drain electrode 18da with the active layer 14 interposed therebetween is smaller than the area of the portion of the gate electrode 12 that overlaps with the source electrode 18s with the active layer 14 interposed therebetween (see FIG. 21(a)).

Even if the configuration on the right side of the intermediate electrode 18ma of the TFT 10A in FIG. 26(a) is made to be the same as the configuration on the right side of the intermediate electrode 18m of the TFT 10 shown in FIG. 21(a), the area of the portion of the gate electrode 12 that overlaps with the drain electrode 18d with the active layer 14 interposed therebetween (see FIG. 21(a)) is smaller than the area of the portion of the gate electrode 12 that overlaps with the source electrode 18sa with the active layer 14 interposed therebetween.

Thus, also when one of the right side or the left side of the intermediate electrode 18ma of the TFT 10A shown in FIG. 26(a) is combined with the TFT 10 shown in FIG. 21(a), it is possible to obtain a configuration where the area of the portion of the gate electrode 12 that overlaps with the drain region is smaller than the area of the portion of the gate electrode 12 that overlaps with the source region.

As described above, by setting the area of the portion of the gate electrode 12 that overlaps with the drain region to be small, it is possible to reduce the OFF current of the TFT. FIG. 27 shows the results obtained of the relationship between the gate voltage Vg (V) and the source-drain current Ids (A) for the TFT 10A shown in FIG. 26(a) and the TFT 10B shown in FIG. 26(b). The horizontal axis of FIG. 27 is the gate voltage Vg (V), and the vertical axis thereof is the source-drain current Ids (A). The results for source-drain voltages Vds (V) of 5 V and 10 V are shown.

Note that the TFT 10B shown in FIG. 26(b) corresponds to what is obtained by switching around the source side and the drain side of the TFT 10A shown in FIG. 26(a). A drain electrode 18db includes a depressed portion 18db1, and an intermediate electrode 18mb includes a protruding portion 18mb2 in the depressed portion 18db1 of the drain electrode 18db. The intermediate electrode 18mb includes a depressed portion 18mb1, and a source electrode 18sb includes a protruding portion 18sb1 in the depressed portion 18mb1 of the intermediate electrode 18mb. Therefore, in the TFT 10B, the area of the portion of the gate electrode 12 that overlaps with the drain region is larger than the area of the portion of the gate electrode 12 that overlaps with the source region.

As can be seen from FIG. 27, the TFT 10A has a smaller OFF current than the TFT 10B whether the source-drain voltage Vds (V) is 5 V or 10 V. Thus, it can be seen that by setting the area of the portion of the gate electrode 12 that overlaps with the drain region to be small, it is possible to reduce the OFF current of the TFT. Where the TFT 10A is used as the second transistor of the shift register described above, it is preferred that the drain electrode 18da is connected to netA (the gate electrode of the first transistor). The source electrode 18sa is connected to VSS, for example.

Note that the magnitude of the OFF current depends on the area of the portion of the gate electrode 12 that overlaps with the drain region, and in that sense the relative magnitude with respect to the area of the portion of the gate electrode 12 that overlaps with the source region is not important. Note however that if the area of the portion of the gate electrode 12 that overlaps with the drain region is set to be small in order to reduce the OFF current of the TFT, an asymmetric configuration is obtained where the area of the portion of the gate electrode 12 that overlaps with the drain region is smaller than the area of the portion of the gate electrode 12 that overlaps with the source region.

As is well known in the art, the characteristics of a TFT depend on the channel width, and it is preferred that the channel width is large. By providing the U-shaped depressed portions 18ma2 and 18sa1 as in the intermediate electrode 18ma and the source electrode 18sa shown in FIG. 26(a), it is possible to make the channel region U-shaped and increase the channel width.

Next, referring to FIG. 28, a structure of another TFT of an embodiment of the present invention will be described.

FIG. 28(a) shows a schematic plan view of a TFT 10C of an embodiment of the present invention. The TFT 10C has a dual-channel structure as does the TFT 10 shown in FIG. 21(a). An intermediate electrode 18mc of the TFT 10C has an H shape, and has a U-shaped depressed portion on the drain side and on the source side. A drain electrode 18dc and a source electrode 18sc each have a protruding portion in the depressed portion of the intermediate electrode 18mc. The area of the portion of the gate electrode 12 that overlaps with the drain region and the area of the portion of the gate electrode 12 that overlaps with the source region are each smaller than the area of the portion of the gate electrode 12 that overlaps with the intermediate region. In the TFT 10C, as compared with the TFT 10, the area of the portion of the gate electrode 12 that overlaps with the drain region is smaller and the width of the two channel regions is larger. Therefore, the TFT 10C has a smaller OFF current and better TFT characteristics than the TFT 10.

FIG. 28(b) shows a schematic plan view of a TFT 10D of an embodiment of the present invention. The TFT 10D has a triple-channel structure including two intermediate electrodes 18md1 and 18md2, as opposed to the TFT 10A shown in FIG. 26(a) having a dual-channel structure. That is, a first channel region is formed between a source electrode 18sd and the first intermediate electrode 18md1, a second channel region is formed between a drain electrode 18dd and the second intermediate electrode 18md2, and a third channel region is formed between the first intermediate electrode 18md1 and the second intermediate electrode 18md2.

Note that although not shown, a first intermediate contact region is formed in the contact layer under the first intermediate electrode 18md1, and a first intermediate region is formed in the active layer under the first intermediate contact region. A second intermediate contact region is formed in the contact layer under the second intermediate electrode 18md2, and a second intermediate region is formed in the active layer under the second intermediate contact region.

For each of the three channels of the TFT 10D, the portion that serves as the drain electrode is a protruding portion (the protruding portions of the intermediate electrodes 18md1 and 18md2 and the protruding portion of the drain electrode 18dd) and the area thereof that that overlaps with the gate electrode 12 is small, thus providing a significant effect of reducing the OFF current. The area of the portion of the gate electrode 12 that overlaps with the drain region and the area of the portion of the gate electrode 12 that overlaps with the source region are each smaller than the area of the portion of the gate electrode 12 that overlaps with the intermediate region. For each of the three channels, the portion that serves as the source electrode has a U-shaped depressed portion, and the protruding portion of the intermediate electrode 18md1, 18md2 or the protruding portion of the drain electrode 18dd is present in each depressed portion. Therefore, the three channel regions have a large width, and have desirable TFT characteristics. Where the TFT 10D is used as the second transistor of the shift register described above, it is preferred that the drain electrode 18dd is connected to netA (the gate electrode of the first transistor).

FIG. 28(c) shows a schematic plan view of a TFT 10E of an embodiment of the present invention. The TFT 10E has a triple-channel structure including two intermediate electrodes 18me1 and 18me2, as does the TFT 10D shown in FIG. 28(b). That is, a first channel region is formed between a source electrode 18se and the first intermediate electrode 18me1, a second channel region is formed between a drain electrode 18de and the second intermediate electrode 18me2, and a third channel region is formed between the first intermediate electrode 18me1 and the second intermediate electrode 18me2. The second intermediate electrode 18me2 has an H shape, and has a U-shaped depressed portion on the drain side and on the source side. The protruding portion of the drain electrode 18de is present in one of the depressed portions of the second intermediate electrode 18me2, and one end of the rectangular first intermediate electrode 18me1 is present in the other depressed portion of the second intermediate electrode 18me2. The source electrode 18se has a U-shaped depressed portion, and the other end of the first intermediate electrode 18me1 is present in the depressed portion of the source electrode 18se.

The TFT 10E also has a configuration where the area of the portion of the gate electrode 12 that overlaps with the drain region is smaller than the area of the portion of the gate electrode 12 that overlaps with the source region, and has an advantage that the OFF current is small. The area of the portion of the gate electrode 12 that overlaps with the drain region and the area of the portion of the gate electrode 12 that overlaps with the source region are each smaller than the area of the portion of the gate electrode 12 that overlaps with the intermediate region. Where the TFT 10E is used as the second transistor of the shift register described above, it is preferred that the drain electrode 18de is connected to netA (the gate electrode of the first transistor).

Referring to FIGS. 29(a)-29(c), a structure of still another TFT of an embodiment of the present invention will be described.

FIG. 29(a) shows a schematic cross-sectional view of a TFT 10F of an embodiment of the present invention. While the TFT 10 shown in FIG. 21 is a channel-etched type TFT, the TFT 10F is different in that it includes an etch stop layer 17.

The TFT 10F is made by adding a step of forming an etch stop layer 17 after the deposition of the micro-crystalline silicon film 14 in the manufacturing process of the TFT 10 shown in FIG. 25. The etch stop layer 17 is formed by, for example, depositing and patterning an SiNₓ film (a thickness of 0.15 μm, for example).

With the presence of the etch stop layer 17, the active layer (micro-crystalline silicon film) 14 is not etched when the contact layer (N⁺ silicon film) 16 is etched so as to divide it into the source contact region 16s, the drain contact region 16d and the intermediate contact region 16m. Therefore, there is an advantage that the thickness of the active layer 14 can be controlled in the deposition step. There is also an advantage that the active layer 14 is not damaged by the etching. Moreover, there is also an advantage that the process stability is high because the gate insulating film 13, the active layer 14 and the etch stop layer 17 can be deposited continuously.

The TFT of an embodiment of the present invention may be a top gate type (staggered type) TFT as shown in FIGS. 29(b) and 29(c).

A TFT 10G shown in FIG. 29(b) includes, formed on the glass substrate 11, a source electrode 18sg, an intermediate electrode 18mg and a drain electrode 18dg, and a source contact region 16sg, a drain contact region 16dg and an intermediate contact region 16mg formed so as to cover these respectively. An active layer 14g is formed so as to cover the source contact region 16sg, the drain contact region 16dg and the intermediate contact region 16mg, and a gate insulating film 13g is formed thereon. A gate electrode 12g is formed so as to overlap with the entirety of the intermediate electrode 18mg (the portion present between the two channels), a portion of the source electrode 18sg and a portion of the drain electrode 18dg, with the gate insulating film 13g interposed therebetween. That is, the TFT 10G also has a double-gate structure similar to that of the TFT 10. Note that a source extension electrode 18sg1 and a drain extension electrode 18dg1 are formed from the same conductive layer as the gate electrode 12g, and are electrically connected to the source electrode 18sg and the drain electrode 18dg, respectively, in contact holes formed in the gate insulating film 13g, the active layer 14g and the contact regions 16sg and 16dg.

Thus, employing a top gate type provides an advantage that the vicinity of the uppermost surface of the active layer 14 formed from the micro-crystalline silicon film can be used as a channel region. When a micro-crystalline silicon film is formed on a substrate, a layer made of amorphous phase which is called an “incubation layer” may be formed in the lowermost layer. Particularly, since the portion in contact with the substrate is formed in the initial period of deposition, it is likely to include voids and has a low mobility. By employing a top gate type, no incubation layer is included in the channel region, and it is therefore possible to make full use of the high mobility of the micro-crystalline silicon film.

A TFT 10H shown in FIG. 29(c) includes an active layer 14h formed on the substrate 11, a source contact region 16sh, a drain contact region 16dh and an intermediate contact region 16mh formed on the active layer 14h. The contact regions are separated by the channel etching as in the TFT 10. A gate insulating film 13h is formed so as to cover the active layer 14h, the source contact region 16sh, the drain contact region 16dh and the intermediate contact region 16mh. A gate electrode 12h is formed so as to overlap with the entirety of the intermediate contact region 16mh (herein serving also as an intermediate electrode) (the portion present between the two channels), a portion of the source contact region 16sh and a portion of the drain contact region 16dh with the gate insulating film 13h interposed therebetween. That is, the TFT 10H also has a double-gate structure similar to that of the TFT 10. Note that a source extension electrode (source electrode) 18sh and a drain extension electrode (drain electrode) 18dh are formed from the same conductive layer as the gate electrode 12h, and are electrically connected to the source extension electrode 18sh and the drain extension electrode 18dh, respectively, in contact holes formed in the gate insulating film 13h, the active layer 14h and the contact layers 16sh and 16dh.

Also having a top gate structure, as does the TFT 10G, the TFT 10H provides an advantage that the vicinity of the uppermost surface of the active layer 14h formed from the micro-crystalline silicon film can be used as a channel region. Moreover, in the TFT 10H, since the intermediate contact region 16mh serves also as an intermediate electrode, there is an advantage that the step of forming the intermediate electrode can be omitted. The configuration where the intermediate contact region serves also as an intermediate electrode is not limited to the TFT 10H, but may also be applied to other TFTs described above.

As described above, the TFT of an embodiment of the present invention may be of either the bottom gate type or the top gate type, and is capable of reducing the OFF current. By including a micro-crystalline silicon film as the active layer, the TFT of an embodiment of the present invention can have a high mobility and a low OFF current. The effect is obtained not only when only a micro-crystalline silicon film is provided as the active layer, but also when a layered film of a micro-crystalline silicon film and an amorphous silicon film is provided. Note that in order to make use of the high mobility of the micro-crystalline silicon film, it is preferred that a micro-crystalline silicon film is provided closer to the gate electrode than an amorphous silicon film so that a channel is formed in the micro-crystalline silicon film. Although the TFT of an embodiment of the present invention has been described herein with an example of a semiconductor film made only of silicon, the embodiment of the present invention is not limited by the type of the semiconductor film, and can be applied to TFTs having other micro-crystalline semiconductor films, e.g., micro-crystalline SiGe films and micro-crystalline SiC films, with which it is desirable to reduce the OFF current. Note that although the use of amorphous silicon or micro-crystalline silicon is advantageous in terms of the mass productivity as described above, polycrystalline silicon may also be used.

### INDUSTRIAL APPLICABILITY

The semiconductor device of the present invention can be widely applied to devices having thin film transistors, including circuit substrates such as active matrix substrates, display devices such as liquid crystal display devices, organic electroluminescence (EL) display devices and inorganic electroluminescence display devices, image sensing devices such as flat panel X-ray image sensor devices, and electronic devices such as image input devices and fingerprint reader devices.

### REFERENCE SIGNS LIST

10, 10A, 10B, 10C, 10D, 10E, 10F, 10G, 10H TFT

11 Substrate (glass substrate)

12 Gate electrode

13 Gate insulating film

14 Active layer (semiconductor layer)

14c1, 14c2 Channel region

14s Source region

14d Drain region

14m Intermediate region

16 Contact layer

16s Source contact region

16d Drain contact region

16m Intermediate contact region

17 Etch stop layer

18s Source electrode

18d Drain electrode

18m Intermediate electrode

19 Protection film

1. A shift register supported by an insulative substrate, wherein:
the shift register includes a plurality of stages each sequentially outputting output signals;
each of the plurality of stages includes a first transistor for outputting the output signals, and a plurality of second transistors whose source region or drain region is electrically connected to a gate electrode of the first transistor; and
the plurality of second transistors include a multi-channel transistor having an active layer including at least two channel regions, a source region and a drain region.

2. The shift register according to claim 1, wherein one of the plurality of second transistors having a highest source-drain voltage is the multi-channel transistor.

3. The shift register according to claim 1, wherein all of the plurality of second transistors are the multi-channel transistors.

4. The shift register according to claim 1, wherein the active layer includes a semiconductor film having an amorphous phase.

5. The shift register according to claim 4, wherein the semiconductor film is a micro-crystalline semiconductor film.

6. The shift register according to claim 1, wherein the active layer includes a polycrystalline semiconductor film.

7. The shift register according to claim 1, wherein:
the gate electrode of the multi-channel transistor has a portion that overlaps with the source region and the drain region;
an area of a portion of the gate electrode that overlaps with the drain region and an area of a portion of the gate electrode that overlaps with the source region are different from each other; and
the area of the portion that is connected to the gate electrode of the first transistor is smaller than the area of the portion that is not connected to the gate electrode of the first transistor.

8. The shift register according to claim 1, wherein a source region and a drain region of the first transistor have different sizes from each other, and one that is not connected to a gate bus line is smaller than one that is connected to the gate bus line.

9. The shift register according to claim 1, wherein:
the active layer of the multi-channel transistor further includes at least one intermediate region formed between the at least two channel regions, and the at least two channel regions include a first channel region formed between the source region and the at least one intermediate region and a second channel region formed between the drain region and the at least one intermediate region;
the multi-channel transistor further includes:
a contact layer including a source contact region in contact with the source region, a drain contact region in contact with the drain region, and at least one intermediate contact region in contact with the at least one intermediate region; and
a source electrode in contact with the source contact region, a drain electrode in contact with the drain contact region, and at least one intermediate electrode in contact with the at least one intermediate contact region;
the gate electrode of the multi-channel transistor opposes the at least two channel regions and the at least one intermediate region with a gate insulating film interposed therebetween; and
an entirety of a portion of the at least one intermediate electrode that is present between the first channel region and the second channel region overlaps with the gate electrode with the at least one intermediate region and the gate insulating film interposed therebetween.

10. The shift register according to claim 9, wherein:
the gate electrode of the multi-channel transistor includes a portion that overlaps with the source region and the drain region; and
an area of a portion of the gate electrode that overlaps with one of the source region and the drain region that is connected to the gate electrode of the first transistor is smaller than an area of a portion of the gate electrode that overlaps with the at least one intermediate region.

11. The shift register according to claim 9, wherein as seen in a direction vertical to the substrate, the at least one intermediate electrode of the multi-channel transistor includes a depressed portion, and the drain electrode includes a protruding portion in the depressed portion of the at least one intermediate electrode.

12. The shift register according to claim 9, wherein as seen in a direction vertical to the substrate, the source electrode of the multi-channel transistor includes a depressed portion, and the at least one intermediate electrode includes a protruding portion in the depressed portion of the source electrode.

13. The shift register according to claim 9, wherein:
the at least one intermediate region of the multi-channel transistor includes a first intermediate region and a second intermediate region, the at least one intermediate contact region includes a first intermediate contact region and a second intermediate contact region, and the at least one intermediate electrode includes a first intermediate electrode and a second intermediate electrode; and
the at least two channel regions further include a third channel region, with the first channel region formed between the source electrode and the first intermediate electrode, the second channel region formed between the drain electrode and the second intermediate electrode, and the third channel region formed between the first intermediate electrode and the second intermediate electrode.

14. An active matrix substrate comprising the shift register according to claim 1.

15. A display panel comprising the shift register according to claim 1.
